(19) United States
(12) Patent Application Publication
(10) Pub. No.: US 2021/0359118 A1
(43) Pub. Date: Nov. 18, 2021

(54) Group III-Nitride High-Electron Mobility Transistors Configured with Recessed Source and/or Drain Contacts for Reduced On State Resistance and Process for Implementing the Same

(71) Applicant: Cree, Inc., Durham, NC (US)

(72) Inventors: Fabian Radulescu, Chapel Hill, NC (US); Scott Sheppard, Chapel Hill, NC (US); Dan Namishia, Wake Forest, NC (US); Chris Hardiman, Morrisville, NC (US); Terry Alcorn, Cary, NC (US); Kyle Bothe, Cary, NC (US); Jennifer Gao, Burlington, NC (US)

(21) Appl. No.: 16/876,752

(22) Filed: May 18, 2020

(51) Int. Cl. H01L 29/778; H01L 29/20; H01L 29/40; H01L 29/66

(52) U.S. Cl. CPC H01L 29/7786; H01L 29/66462; H01L 29/402; H01L 29/2003

(57) ABSTRACT

A high-electron mobility transistor (HEMT) that includes a substrate, a group III-Nitride channel layer on the substrate, a group III-Nitride barrier layer on the group III-Nitride channel layer, the group III-Nitride barrier layer that includes a higher bandgap than a bandgap of the group III-Nitride channel layer, a source electrically coupled to the group III-Nitride barrier layer, a gate electrically coupled to the group III-Nitride barrier layer, and a drain electrically coupled to the group III-Nitride barrier layer. The source and/or the drain are structured and arranged to extend through the group III-Nitride barrier layer into the group III-Nitride channel layer.

### FIELD OF THE DISCLOSURE

The disclosure relates to gallium nitride high-electron mobility transistors with recessed source and/or drain contacts. The disclosure also relates to a process of implementing gallium nitride high-electron mobility transistors with recessed source and/or drain contacts. The disclosure further relates to gallium nitride high-electron mobility transistors with recessed source and/or drain contacts for reduced on state resistance. The disclosure also relates to a process of implementing gallium nitride high-electron mobility transistors with recessed source and/or drain contacts for reduced on state resistance. The disclosure further relates to gallium nitride high-electron mobility transistors with recessed source and/or drain contacts configured to reduce on state resistance. The disclosure also relates to a process of implementing gallium nitride high-electron mobility transistors with recessed source and/or drain contacts configured to reduce on state resistance.

### BACKGROUND OF THE DISCLOSURE

Group III-Nitride based high-electron mobility transistors (HEMTs) are very promising candidates for high power radiofrequency (RF) applications, and also for low frequency high power switching applications since the material properties of Group III-nitrides, such as GaN and its alloys, enable achievement of high voltage and high current, along with high RF gain and linearity for RF applications. A typical Group III-nitride HEMT relies on the formation of a two-dimensional electron gas (2DEG) formed at the interface between a higher band-gap Group-III nitride (e.g., AlGaN) barrier layer and a lower band-gap Group-III nitride material (e.g., GaN) channel layer, where the smaller bandgap material has a higher electron affinity. The 2DEG is an accumulation layer in the smaller bandgap material and can contain a high electron concentration and high electron mobility.

An important issue in Group III-Nitride based high-electron mobility transistors (HEMTs) is ON-state resistance RDS(on). In this regard, ON-state resistance RDS(on) can result in increased conduction losses, increased switching losses, reduced current carrying capability, and/or the like performance issues. The ON-state resistance RDS(on) may be a result of trapping effects characteristic of Group III-Nitride based high-electron mobility transistors (HEMTs).

Accordingly, there is a need for a solution to address and reduce an ON-state resistance RDS(on) in Group-III nitride HEMTs and improve the performance of such devices.

### SUMMARY OF THE DISCLOSURE

One aspect includes a high-electron mobility transistor (HEMT) that includes: a substrate; a group III-Nitride channel layer on the substrate; a group III-Nitride barrier layer on the group III-Nitride channel layer, the group III-Nitride barrier layer that includes a higher bandgap than a bandgap of the group III-Nitride channel layer; a source electrically coupled to the group III-Nitride barrier layer; a gate electrically coupled to the group III-Nitride barrier layer; and a drain electrically coupled to the group III-Nitride barrier layer, where at least one of the source and the drain are structured and arranged to extend through the group III-Nitride barrier layer and into the group III-Nitride channel layer.

One aspect includes a process of implementing a high-electron mobility transistor (HEMT) that includes: providing a substrate; providing a group III-Nitride channel layer on the substrate; providing a group III-Nitride barrier layer on the group III-Nitride channel layer, the group III-Nitride barrier layer that includes a higher bandgap than a bandgap of the group III-Nitride channel layer; modifying the group III-Nitride barrier layer to receive a source and electrically coupling the source to the group III-Nitride barrier layer; electrically coupling a gate to the group III-Nitride barrier layer; and modifying the group III-Nitride barrier layer and arranging at least one of a source and a drain to extend through the group III-Nitride barrier layer and into the group III-Nitride channel layer.

Additional features, advantages, and aspects of the disclosure may be set forth or apparent from consideration of the following detailed description, drawings, and claims. Moreover, it is to be understood that both the foregoing summary of the disclosure and the following detailed description are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 shows a partial cross-sectional view of one aspect of a transistor according to the disclosure.

FIG. 2 shows a detailed partial cross-sectional view of the transistor of FIG. 1.

FIG. 3 shows a partial cross-sectional view of one aspect of a transistor according to the disclosure.

FIG. 4 shows a detailed partial cross-sectional view of the transistor of FIG. 3.

FIG. 5 shows a cross-sectional view of another aspect of a transistor according to FIG. 1 and FIG. 2

FIG. 6 shows a cross-sectional view of another aspect of a transistor according to FIG. 3 and FIG. 4.

FIG. 7 shows a cross-sectional view of another aspect of a transistor according to FIG. 1 and FIG. 2.

FIG. 8 shows a cross-sectional view of another aspect of a transistor according to FIG. 3 and FIG. 4.

FIG. 9 shows a cross-sectional view of another aspect of a transistor according to FIG. 1 and FIG. 2.

FIG. 10 shows a cross-sectional view of another aspect of a transistor according to FIG. 3 and FIG. 4.

FIG. 11 shows a cross-sectional view of another aspect of a transistor according to FIG. 1 and FIG. 2.

FIG. 12 shows a cross-sectional view of another aspect of a transistor according to FIG. 3 and FIG. 4.

FIG. 13 shows a cross-sectional view of another aspect of a transistor according to FIG. 1 and FIG. 2.

FIG. 14 shows a cross-sectional view of another aspect of a transistor according to FIG. 3 and FIG. 4.

FIG. 15 includes FIG. 15A and FIG. 15B graphically illustrating resistance within transistors.

FIG. 16 shows a detailed partial cross-sectional view of the transistor of FIG. 1 and/or FIG. 3.

FIG. 17 shows a process of implementing a transistor according to the disclosure.

### DETAILED DESCRIPTION OF THE DISCLOSURE

The aspects of the disclosure and the various features and advantageous details thereof are explained more fully with reference to the non-limiting aspects and examples that are described and/or illustrated in the accompanying drawings and detailed in the following description. It should be noted that the features illustrated in the drawings are not necessarily drawn to scale, and features of one aspect may be employed with other aspects, as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings and in the different aspects disclosed.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The disclosure includes both extrinsic and intrinsic semiconductors. Intrinsic semiconductors are undoped (pure). Extrinsic semiconductors are doped, meaning an agent has been introduced to change the electron and hole carrier concentration of the semiconductor at thermal equilibrium. Both p-type and n-type semiconductors are disclosed, with p-types having a larger hole concentration than electron concentration, and n-types having a larger electron concentration than hole concentration.

Silicon carbide (SiC) has excellent physical and electronic properties, which should theoretically allow production of electronic devices that can operate at higher temperatures, higher power, and higher frequency than devices produced from silicon (Si) or gallium arsenide (GaAs) substrates. The high electric breakdown field of about 4×E6 V/cm, high saturated electron drift velocity of about 2.0×E7 cm/sec and high thermal conductivity of about 4.9 W/cm-° K indicate that SiC would be suitable for high frequency and high power applications. In some aspects, the transistor of the present disclosure comprises Si, GaAs or other suitable substrates.

This disclosure relates to a novel ohmic window etch process, which defines an open area on which the source and drain contacts will be placed through, for example, a self-aligned ohmic evaporation process. Traditionally, the ohmic contacts are situated directly on an AlGaN barrier surface. The process included etching through the first passivation dielectric and evaporation of the ohmic metal contacts followed by solvent-based liftoff.

The disclosure addresses the deficiencies of the traditional devices and processes. In particular, to reduce the contact resistance of these ohmic metal contacts, the disclosed etch process etches through the first passivation, recesses through the AlGaN barrier, and terminates on the GaN within the two-Dimensional Electron Gas (2DEG) region, which is the main channel of electron flow in the AlGaN/GaN HEMT device. Therefore, the ohmic metal contacts are now situated directly in the 2DEG region of the device. With the new process utilizing the AlGaN recess, a roughly 13% reduction in ON-state resistance RDS(on) has been achieved across all RF technologies. This is directly due to the reduction in contact resistance of the ohmic source-drain metal contacts. The disclosure provides numerous advantages including a sizeable reduction in ON-state resistance RDS(on) of all RF technology and the ability to transfer the ohmic window etch process to a high capacity/high volume manufacturing (HVM) tool.

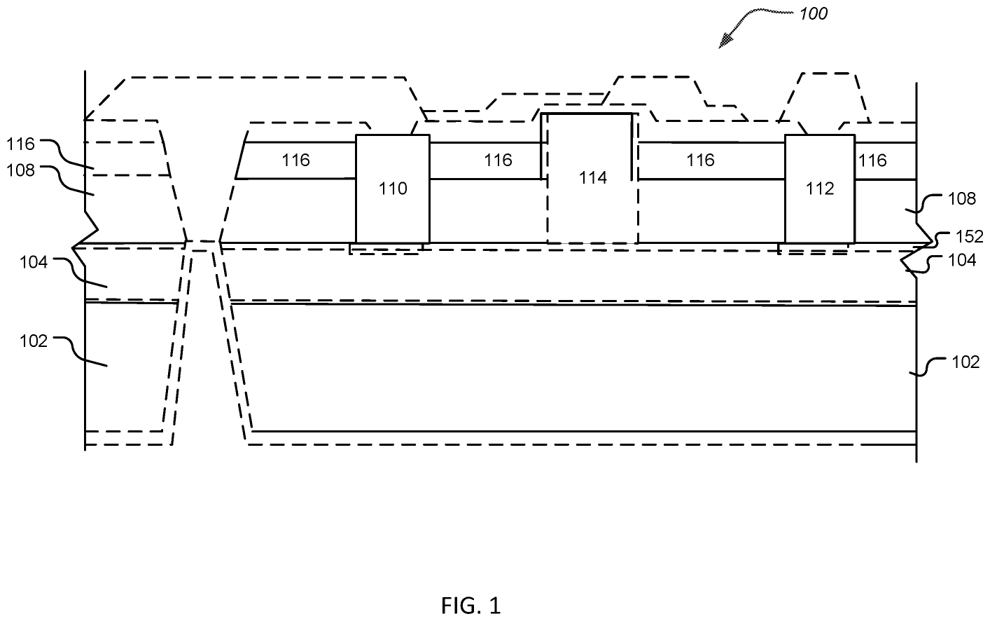

FIG. 1 shows a cross-sectional view of an aspect of a transistor according to the disclosure.

In particular, FIG. 1 shows a cross-sectional view of a transistor 100. The transistor 100 may include a substrate layer 102, a channel layer 104, a barrier layer 108, a source 110, a drain 112, a spacer layer 116, and a gate 114. Each of these structures of the transistor 100 are described in greater detail below. In one aspect, a bandgap of the channel layer 104 may be less than a bandgap of the barrier layer 108 to form a two-dimensional electron gas (2DEG) at a heterointerface 152 between the channel layer 104 and barrier layer 108 when biased at an appropriate level. In one aspect, the heterointerface 152 may form and/or define a two-dimensional electron gas (2DEG) region. Additionally, the transistor 100 of FIG. 1 may further include any one or more other aspects as described herein.

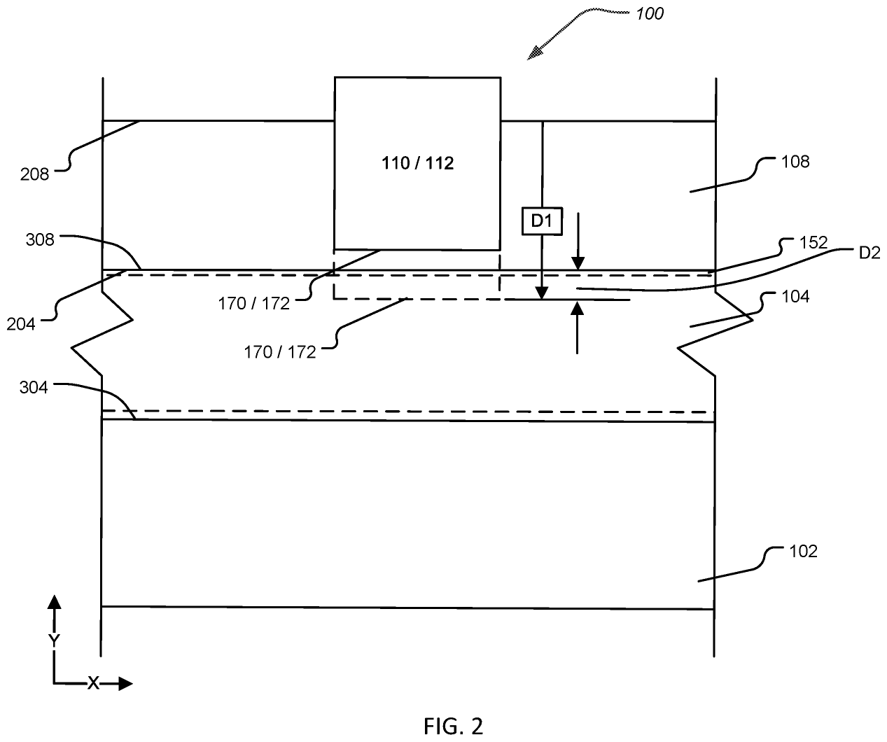

In one aspect, the source 110 may be structured and arranged to extend partially through the barrier layer 108, the source 110 may be structured and arranged to extend completely through the barrier layer 108, the source 110 may be structured and arranged to extend through the barrier layer 108 and extend partially through the channel layer 104, and/or the source 110 may be structured and arranged to extend through the barrier layer 108 and extend to the heterointerface 152 as further described with reference to FIG. 2. The structural arrangement and configuration of the source 110 as described herein reduces ON-state resistance RDS(on) for the transistor 100. Moreover, the structural arrangement and configuration of the source 110 as described herein reduces ON-state resistance RDS(on) for the transistor 100 across all technologies including radio frequency (RF) technologies. In this regard, the ON-state resistance RDS(on) may be reduced by 4%-40%, 4%-8%, 8%-12%, 12%-16%, 16%-20%, 20%-24%, 24%-28%, 28%-32%, 32%-36% or 36%-40%.

In one or more aspects, the source 110 may be formed and/or defined by an open area for placement of the source 110. The open area may be part of an ohmic window etch process. Additionally, the source 110 may be placed utilizing a self-aligned ohmic evaporation process. In this regard, the process may include etching through one or more of the spacer layer 116, the barrier layer 108, and/or the channel layer 104, evaporation of the ohmic metal contacts, and a solvent-based liftoff. Accordingly, the source 110 may be arranged and/or situated consistent with the disclosure as described herein.

In one aspect, the drain 112 may be structured and arranged to extend partially through the barrier layer 108, the drain 112 may be structured and arranged to extend completely through the barrier layer 108, the drain 112 may be structured and arranged to extend through the barrier layer 108 and extend partially through the channel layer 104, and/or the drain 112 may be structured and arranged to extend through the barrier layer 108 and extend to the heterointerface 152 as further described with reference to FIG. 2. The structural arrangement and configuration of the drain 112 as described herein reduces ON-state resistance RDS(on) for the transistor 100. Moreover, the structural arrangement and configuration of the drain 112 as described herein reduces ON-state resistance RDS(on) for the transistor 100 across all technologies including radio frequency (RF) technologies. In this regard, the ON-state resistance RDS(on) may be reduced by 4%-40%, 4%-8%, 8%-12%, 12%-16%, 16%-20%, 20%-24%, 24%-28%, 28%-32%, 32%-36% or 36%-40%.

In one or more aspects, the drain 112 may be formed and/or defined by an open area for placement of the drain 112. The open area may be part of an ohmic window etch process. Additionally, the drain 112 may be placed utilizing a self-aligned ohmic evaporation process. In this regard, the process may include etching through one or more of the spacer layer 116, the barrier layer 108, and/or the channel layer 104, evaporation of the ohmic metal contacts, and a solvent-based liftoff. Accordingly, the drain 112 may be arranged and/or situated consistent with the disclosure as described herein.

The substrate layer 102 may be made of Silicon Carbide (SiC). In some aspects, the substrate layer 102 may be a semi-insulating SiC substrate, a p-type substrate, an n-type substrate, and/or the like. In some aspects, the substrate layer 102 may be very lightly doped. In one aspect, the background impurity levels may be low. In one aspect, the background impurity levels may be 1E15/cm³ or less. In one aspect, the substrate layer 102 may be formed of SiC selected from the group of 6H, 4H, 15R, 3C SiC, or the like, and the SiC may be semi-insulating and doped with vanadium or any other suitable dopant or undoped of high purity with defects providing the semi-insulating properties.

In another aspect, the substrate layer 102 may be GaAs, GaN, or other material suitable for the applications described herein. In another aspect, the substrate layer 102 may include sapphire, spinel, ZnO, silicon, or any other material capable of supporting growth of Group III-nitride materials.

In one aspect, the channel layer 104 may be high purity GaN. In one aspect, the channel layer 104 may be high purity GaN that may be a low-doped n-type. In one aspect, the channel layer 104 may also use a higher band gap Group III-nitride layer as a back barrier, such as an AlGaN back barrier, on the other side of the channel layer 104 from the barrier layer 108 to achieve better electron confinement. In one aspect, the channel layer 104 may be a group III-Nitride channel layer.

In one aspect, the channel layer 104 may have a channel layer thickness defined as a distance between an upper surface of the substrate layer 102 and a lower surface of the barrier layer 108. In one aspect, the channel layer thickness may be less than 0.8 microns, less than 0.7 microns, less than 0.6 microns, less than 0.5 microns, or less than 0.4 microns. In one aspect, the channel layer thickness may have a range of 0.8 microns to 0.6 microns, 0.7 microns to 0.5 microns, 0.6 microns to 0.4 microns, 0.5 microns to 0.3 microns, 0.4 microns to 0.2 microns, or 0.7 microns to 0.3 microns.

In one aspect, the channel layer 104 includes a Group III-nitride, and, in particular includes GaN. The channel layer 104 may include a first channel sublayer and a second channel sublayer formed on the first channel sublayer. The first channel sublayer may be doped with Fe. In one aspect, the transistor 100 may have an intervening layer(s) thickness defined as a length between an upper surface of the substrate layer 102 and a lower surface of the barrier layer 108. In one aspect, the intervening layer(s) thickness may be less than 0.8 microns, less than 0.7 microns, less than 0.6 microns, less than 0.5 microns, or less than 0.4 microns. In one aspect, the intervening layer(s) thickness may have a range of 0.8 microns to 0.6 microns, 0.7 microns to 0.5 microns, 0.6 microns to 0.4 microns, 0.5 microns to 0.3 microns, or 0.4 microns to 0.2 microns.

The barrier layer 108 may be formed on the channel layer 104. In one aspect, the barrier layer 108 may be formed directly on the channel layer 104, and in other aspects, the barrier layer 108 is formed on the channel layer 104 with intervening layer(s). Depending on the embodiment, the barrier layer 108 can include additional layers on the channel layer 104. For example an AlN layer or an AlGaN layer can be positioned on the channel layer 104 and an AlGaN layer with a lower percentage Al concentration can be positioned above the AlN layer or a higher Al percentage layer as described in U.S. Pat. No. 6,885,076 (Semiconductor laser device—filed Jun. 21, 2000) hereby incorporated by reference in its entirety. Furthermore, additional layers may be positioned above or in the barrier layer 108, such as spacer layers and/or other layers. Depending on the aspect, the channel layer 104 may be formed of different suitable materials such as a Group III-nitride such as AlₓGa_{y}In_{(1-x-y)}N (where 0<=x<=1, 0<=y<=1, x+y<=1), e.g., AlGaN, AlN, or InAlGaN, or another suitable material. In one aspect, the barrier layer 108 may be a group III-Nitride barrier layer. In one aspect, the barrier layer 108 may be AlGaN, and in another aspect the barrier layer 108 is AlN. In one aspect, the barrier layer 108 may be undoped. In one aspect, the barrier layer 108 may be doped. In one aspect, the barrier layer 108 may be an n-type material. In some aspects, the barrier layer 108 may have multiple layers of n-type material having different carrier concentrations. In one aspect, the barrier layer 108 may be a Group III-nitride or a combination thereof. In one aspect, the barrier layer 108 may include a first barrier sublayer on the channel layer 104 and a second barrier sublayer on the first barrier sublayer. The first barrier sublayer may include AlN. The second barrier sublayer may include AlₓGa₁₋ₓN. In one aspect, a bandgap of the channel layer 104 may be less than a bandgap of the barrier layer 108 to form a two-dimensional electron gas (2DEG) at a heterointerface 152 between the channel layer 104 and barrier layer 108 when biased at an appropriate level. In one aspect, a bandgap of the channel layer 104 that may be GaN may be less than a bandgap of the barrier layer 108 that may be AlGaN to form the two-dimensional electron gas (2DEG) at a heterointerface 152 between the channel layer 104 and barrier layer 108 when biased at an appropriate level.

In one aspect, the gate 114 may be formed on the barrier layer 108. The gate 114 may be arranged directly on the barrier layer 108 or the gate 114 may be arranged on intervening layer(s) on the barrier layer 108, such as an AlGaN layer on an AlN barrier layer. Other or additional intervening layers are possible. In some aspects, the gate 114 may be deposited in a channel formed in the spacer layer 116, for example, a channel formed by etching or the like using semiconductor processing techniques understood by those of ordinary skill in the art. The gate 114 may have a T-shaped cross-section. Other gate configurations, gate shapes, and/or the like are contemplated by this disclosure for implementation as the gate 114.

The transistor 100 may include a spacer layer 116. The spacer layer 116 may be formed of SiN, AlO, SiO, SiO₂, AlN, or the like or combinations thereof. The spacer layer 116 may be provided on the barrier layer 108 or other intervening layers. To protect and separate the gate 114, the source 110, and/or the drain 112, the spacer layer 116 may be arranged on the barrier layer 108, on a side opposite the channel layer 104, adjacent the gate 114, the drain 112, and/or the source 110. The spacer layer 116 may be a passivation layer made of SiN, AlO, SiO, SiO₂, AlN, or the like, or a combination incorporating multiple layers thereof. In one aspect, the spacer layer 116 is a passivation layer made of SiN. In one aspect, the spacer layer 116 can be deposited using MOCVD, plasma chemical vapor deposition (CVD), hot-filament CVD, or sputtering. In one aspect, the spacer layer 116 may include deposition of Si₃N₄. In one aspect, the spacer layer 116 forms an insulating layer. In one aspect, the spacer layer 116 forms an insulator. In one aspect, the spacer layer 116 may be a dielectric. In one aspect, the spacer layer 116 may include a number of different layers of dielectrics or a combination of dielectric layers. In one aspect, the spacer layer 116 may be many different thicknesses, with a suitable range of thicknesses being approximately 0.05 to 2 microns. In one aspect, the spacer layer 116 may include a material such as a Group III nitride material having different Group III elements such as alloys of Al, Ga, or In, with a suitable spacer layer material being AlₓIn_{y}Ga_{1-x-y} (where 0<=x<=1 and 0<=y<=1, x+y<=1).

FIG. 2 shows a detailed partial cross-sectional view of the transistor of FIG. 1.

In particular, FIG. 2 illustrates further details of the structural configuration and arrangement of the source 110 and the drain 112 in a single illustration for ease of understanding. However, the source 110 may have a structural configuration and/or arrangement consistent with FIG. 2 as described herein, which may be different from the drain 112 that has a structural configuration and/or arrangement consistent with FIG. 2 as described herein. Alternatively, the source 110 may have a structural configuration and/or arrangement consistent in regards to at least one aspect with the drain 112.

In one aspect, the source 110 may be structured and arranged to extend partially through the barrier layer 108, the source 110 may be structured and arranged to extend completely through all of the layers of the barrier layer 108, the source 110 may be structured and arranged to extend completely through the barrier layer 108 to the heterointerface 152, the source 110 may be structured and arranged to extend completely through the barrier layer 108 and extend partially through the channel layer 104, the source 110 may be structured and arranged to extend through the heterointerface 152, and/or the source 110 may be structured and arranged to extend below the heterointerface 152.

With reference to FIG. 2, the barrier layer 108 may include an upper surface 208 and a lower surface 308. The upper surface 208 of the barrier layer 108 may extend generally along the x-axis or horizontal axis. The lower surface 308 of the barrier layer 108 may extend generally along the x-axis or horizontal axis. The upper surface 208 of the barrier layer 108 may extend generally parallel to the lower surface 308 of the barrier layer 108. In this regard, generally is defined as being within 1°-20°. The upper surface 208 of the barrier layer 108 may be defined as being vertically above the lower surface 308 of the barrier layer 108 along the y-axis or vertical axis.

With further reference to FIG. 2, the channel layer 104 may include an upper surface 204 and a lower surface 304. The upper surface 204 of the channel layer 104 may extend generally along the x-axis or horizontal axis. The lower surface 304 of the channel layer 104 may extend generally along the x-axis or horizontal axis. The upper surface 204 of the channel layer 104 may extend generally parallel to the lower surface 304 of the channel layer 104. In this regard, generally is defined as being within 1°-20°. The upper surface 204 of the channel layer 104 may be defined as being vertically above the lower surface 304 of the channel layer 104 along the y-axis or vertical axis.

In one aspect, the source 110 may be structured and arranged to extend vertically along the y-axis through the upper surface 208 of the barrier layer 108 and partially through the barrier layer 108 towards the lower surface 308 of the barrier layer 108.

In one aspect, the source 110 may be structured and arranged to extend vertically along the y-axis through the upper surface 208 of the barrier layer 108, through the barrier layer 108, and to the lower surface 308 of the barrier layer 108.

In one aspect, the source 110 may be structured and arranged to extend vertically along the y-axis through the upper surface 208 of the barrier layer 108, through the barrier layer 108, and through the lower surface 308 of the barrier layer 108.

In one aspect, the source 110 may be structured and arranged to extend vertically along the y-axis through the upper surface 208 of the barrier layer 108, through the barrier layer 108, through the lower surface 308 of the barrier layer 108, and through the upper surface 204 of the channel layer 104.

In one aspect, the source 110 may be structured and arranged to extend vertically along the y-axis through the upper surface 208 of the barrier layer 108, through the barrier layer 108, through the lower surface 308 of the barrier layer 108, and through the upper surface 204 of the channel layer 104 to the heterointerface 152.

In one aspect, the source 110 may be structured and arranged to extend vertically along the y-axis through the upper surface 208 of the barrier layer 108, through the barrier layer 108, through the lower surface 308 of the barrier layer 108, through the upper surface 204 of the channel layer 104, and partially through the channel layer 104.

With further reference to FIG. 2, a depth that the source 110 is structurally arranged and configured within the transistor 100 is illustrated with respect to a distance D1 along the y-axis or vertical axis. The distance D1 being defined as a percentage of the thickness of the barrier layer 108. In one or more aspects, the distance D1 may be 80% to 120% of the thickness of the barrier layer 108, 80% to 90% of the thickness of the barrier layer 108, 90% to 95% of the thickness of the barrier layer 108, 95% to 99% of the thickness of the barrier layer 108, 99% to 100% of the thickness of the barrier layer 108, 100% to 101% of the thickness of the barrier layer 108, 99% to 101% of the thickness of the barrier layer 108, 101% to 102% of the thickness of the barrier layer 108, 102% to 105% of the thickness of the barrier layer 108, 105% to 110% of the thickness of the barrier layer 108, or 110% to 120% of the thickness of the barrier layer 108. In this regard, distances greater than 100% are indicative of distances into the channel layer 104.

In one aspect, the source 110 may be structured and arranged to extend vertically along the y-axis through the barrier layer 108 and partially through the channel layer 104 a distance D2. In one aspect, the distance D2 may be 50 Å-1000 Å, 50 Å-150 Å, 150 Å-250 Å, 250 Å-500 Å, 500 Å-800 Å, or 800 Å-1000 Å. In one aspect, the distance D2 may be defined as a percentage of the thickness of the channel layer 104. In one or more aspects, the distance D2 may be 1% to 10%, 1% to 2%, 2% to 3%, 3% to 4%, 4% to 5%, 5% to 6%, 6% to 7%, 7% to 8%, 8% to 9%, or 9% to 10%, of the thickness of the channel layer 104.

In one aspect, the source 110 may be structured and arranged to have a lower surface 170 as illustrated in FIG. 2. The lower surface 170 of the source 110 may extend generally parallel to one or more of the upper surface 208, the lower surface 308, the upper surface 204, and/or the lower surface 304. In this regard, generally is defined as being within 1°-20°.

Depending on the embodiment, the lower surface 170 of the source 110 may be vertically below (along the y-axis) the upper surface 208, may be within the barrier layer 108, may be on the lower surface 308, may be directly on the lower surface 308, may be within the lower surface 308, may be vertically below the lower surface 308, may be on the upper surface 204, may be directly on the upper surface 204, may be within the upper surface 204, may be vertically below the upper surface 204, may be on the heterointerface 152, may be directly on the heterointerface 152, may be vertically below the heterointerface 152, may be within the heterointerface 152, and/or may be within the channel layer 104.

The structural arrangement and configuration of the source 110 as described herein reduces ON-state resistance RDS(on) for the transistor 100. Moreover, the structural arrangement and configuration of the source 110 as described herein reduces ON-state resistance RDS(on) for the transistor 100 across all technologies including radio frequency (RF) technologies. In this regard, the ON-state resistance RDS(on) may be reduced by 4%-40%, 4%-8%, 8%-12%, 12%-16%, 16%-20%, 20%-24%, 24%-28%, 28%-32%, 32%-36% or 36%-40%.

In one aspect, the drain 112 may be structured and arranged to extend partially through the barrier layer 108, the drain 112 may be structured and arranged to extend completely through all of the layers of the barrier layer 108, the drain 112 may be structured and arranged to extend completely through the barrier layer 108 to the heterointerface 152, the drain 112 may be structured and arranged to extend partially through the channel layer 104, the drain 112 may be structured and arranged to extend through the heterointerface 152, and/or the drain 112 may be structured and arranged to extend below the heterointerface 152.

FIG. 2 illustrates further details of the structural configuration and arrangement of the drain 112. In one aspect, the drain 112 may be structured and arranged to extend vertically along the y-axis through the upper surface 208 of the barrier layer 108 and partially through the barrier layer 108 towards the lower surface 308 of the barrier layer 108.

In one aspect, the drain 112 may be structured and arranged to extend vertically along the y-axis through the upper surface 208 of the barrier layer 108, through the barrier layer 108, and to the lower surface 308 of the barrier layer 108.

In one aspect, the drain 112 may be structured and arranged to extend vertically along the y-axis through the upper surface 208 of the barrier layer 108, through the barrier layer 108, through the lower surface 308 of the barrier layer 108.

In one aspect, the drain 112 may be structured and arranged to extend vertically along the y-axis through the upper surface 208 of the barrier layer 108, through the barrier layer 108, through the lower surface 308 of the barrier layer 108, and through the upper surface 204 of the channel layer 104.

In one aspect, the drain 112 may be structured and arranged to extend vertically along the y-axis through the upper surface 208 of the barrier layer 108, through the barrier layer 108, through the lower surface 308 of the barrier layer 108, and through the upper surface 204 of the channel layer 104 to the heterointerface 152.

In one aspect, the drain 112 may be structured and arranged to extend vertically along the y-axis through the upper surface 208 of the barrier layer 108, through the barrier layer 108, through the lower surface 308 of the barrier layer 108, through the upper surface 204 of the channel layer 104, and partially through the channel layer 104.

With further reference to FIG. 2, a depth that the drain 112 is structurally arranged and configured within the transistor 100 is illustrated with respect to the distance D1 along the y-axis or vertical axis. The distance D1 being defined as a percentage of the thickness of the barrier layer 108. In one or more aspects, the distance D1 may be 80% to 120% of the thickness of the barrier layer 108, 80% to 90% of the thickness of the barrier layer 108, 90% to 95% of the thickness of the barrier layer 108, 95% to 99% of the thickness of the barrier layer 108, 99% to 100% of the thickness of the barrier layer 108, 100% to 101% of the thickness of the barrier layer 108, 99% to 101% of the thickness of the barrier layer 108, 101% to 102% of the thickness of the barrier layer 108, 102% to 105% of the thickness of the barrier layer 108, 105% to 110% of the thickness of the barrier layer 108, or 110% to 120% of the thickness of the barrier layer 108. In this regard, distances greater than 100% are indicative of distances into the channel layer 104.

In one aspect, the drain 112 may be structured and arranged to extend vertically along the y-axis through the barrier layer 108 and partially through the channel layer 104 a distance D2. In one aspect, the distance D2 may be 50 Å-1000 Å, 50 Å-150 Å, 150 Å-250 Å, 250 Å-500 Å, 500 Å-800 Å, or 800 Å-1000 Å. In one aspect, the distance D2 may be defined as a percentage of the thickness of the channel layer 104. In one or more aspects, the distance D2 may be 1% to 10%, 1% to 2%, 2% to 3%, 3% to 4%, 4% to 5%, 5% to 6%, 6% to 7%, 7% to 8%, 8% to 9%, or 9% to 10%, of the thickness of the channel layer 104.

In one aspect, the drain 112 may be structured and arranged to have a lower surface 172 as illustrated in FIG. 2. The lower surface 172 of the drain 112 may extend generally parallel to one or more of the upper surface 208, the lower surface 308, the upper surface 204, and/or the lower surface 304. In this regard, generally is defined as being within 1°-20°.

Depending on the embodiment, the lower surface 172 of the drain 112 may be vertically below (along the y-axis) the upper surface 208, may be within the barrier layer 108, may be on the lower surface 308, may be directly on the lower surface 308, may be within the lower surface 308, may be vertically below the lower surface 308, may be on the upper surface 204, may be directly on the upper surface 204, may be within the upper surface 204, may be vertically below the upper surface 204, may be on the heterointerface 152, may be directly on the heterointerface 152, may be vertically below the heterointerface 152, may be within the heterointerface 152, and/or may be within the channel layer 104.

The structural arrangement and configuration of the drain 112 as described herein reduces ON-state resistance RDS(on) for the transistor 100. Moreover, the structural arrangement and configuration of the drain 112 as described herein reduces ON-state resistance RDS(on) for the transistor 100 across all technologies including radio frequency (RF) technologies. In this regard, the ON-state resistance RDS(on) may be reduced by 4%-40%, 4%-8%, 8%-12%, 12%-16%, 16%-20%, 20%-24%, 24%-28%, 28%-32%, 32%-36%, or 36%-40%.

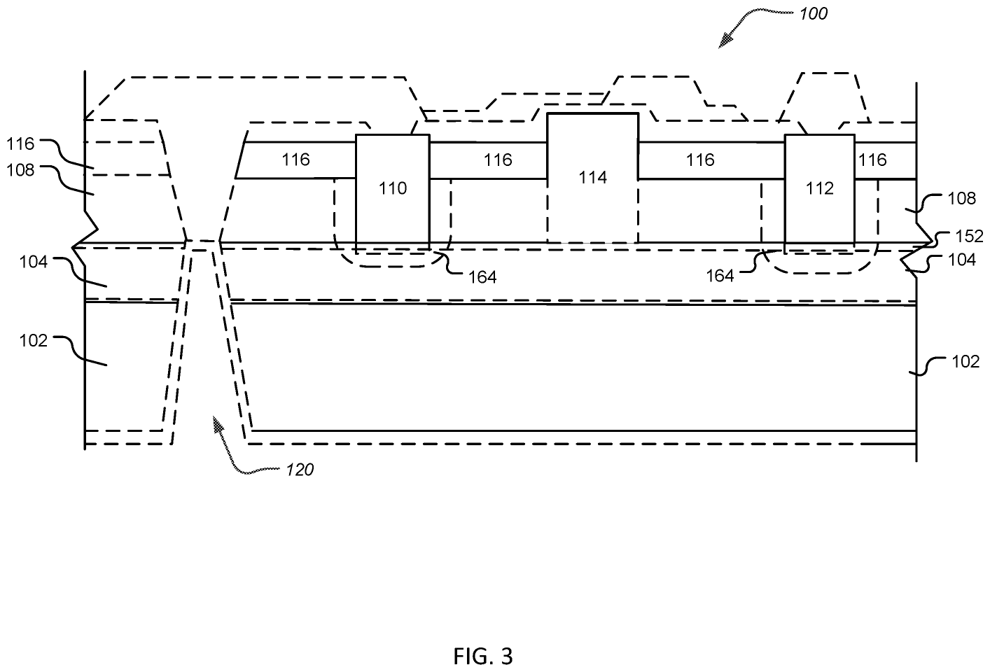

FIG. 3 shows a partial cross-sectional view of one aspect of a transistor according to the disclosure.

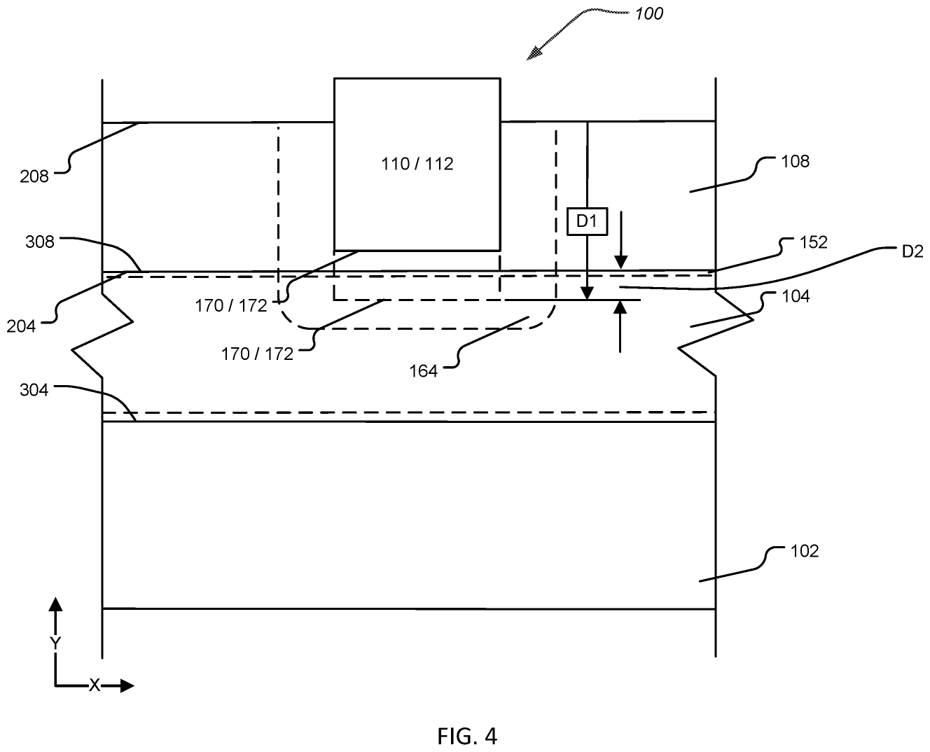

FIG. 4 shows a detailed partial cross-sectional view of the transistor of FIG. 3.

FIG. 3 and FIG. 4 show different aspects and/or features of the transistor 100 of the present disclosure with like reference numerals representing the same or analogous parts in the various aspects and figures of the disclosure. It should be understood that a feature described in one aspect of the disclosure or illustrated in a Figure can be added to another aspect or replace a feature in another aspect. In this regard, the transistor 100 of FIG. 3 and FIG. 4 may further include any one or more other aspects as described herein.

With reference to FIG. 3 and FIG. 4, the transistor 100 may be configured such that the barrier layer 108 may include a region 164 under and/or adjacent the source 110 and/or the drain 112 that may be a N+ material. In one aspect, the barrier layer 108 may include the region 164 under and/or an adjacent the source 110 and/or drain 112 that is Si doped. In one aspect, the region 164 may be implanted. In one aspect, the region 164 may be implanted with n-type dopants. In one aspect, the region 164 may additionally be located in the channel layer 104. In one aspect, the region 164 may be located only in the channel layer 104. In one aspect, the region 164 may be located only in the barrier layer 108. It should be noted that in contrast to the implementation of the transistor 100 in FIG. 3 and FIG. 4, the implementation of the transistor 100 in FIG. 1 and FIG. 2 is implemented without the region 164.

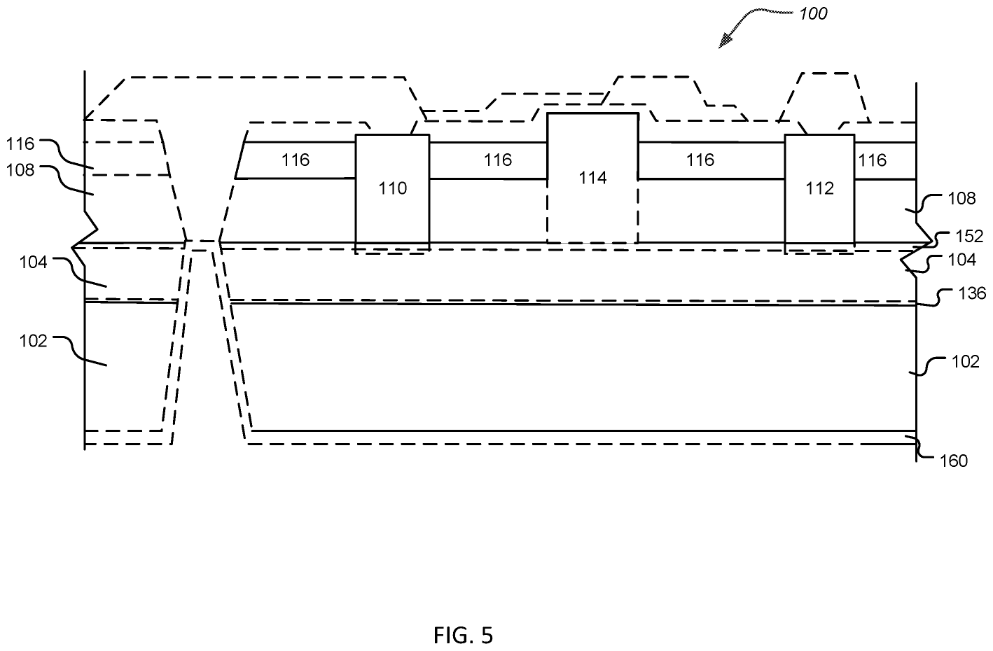

FIG. 5 shows a cross-sectional view of another aspect of a transistor according to FIG. 1 and FIG. 2.

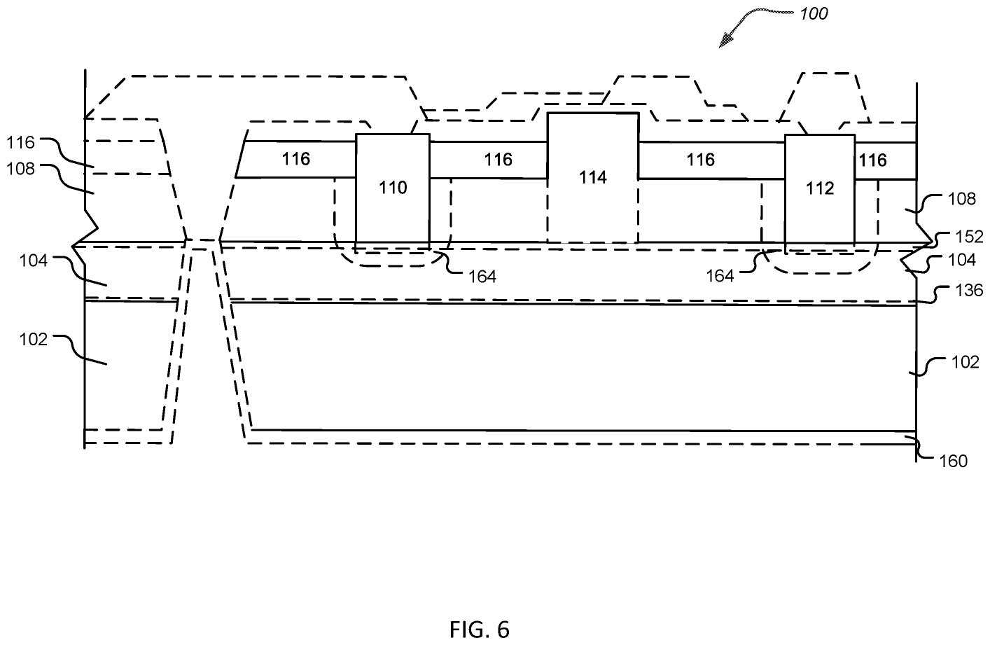

FIG. 6 shows a cross-sectional view of another aspect of a transistor according to FIG. 3 and FIG. 4.

FIG. 5 and FIG. 6 show different aspects and/or features of the transistor 100 of the present disclosure with like reference numerals representing the same or analogous parts in the various aspects and figures of the disclosure. It should be understood that a feature described in one aspect of the disclosure or illustrated in a Figure can be added to another aspect or replace a feature in another aspect. In this regard, the transistor 100 of FIG. 5 and FIG. 6 may further include any one or more other aspects as described herein.

With reference to FIG. 5 and FIG. 6, the transistor 100 may include a nucleation layer 136. In this regard, depending on the material of the substrate layer 102, the nucleation layer 136 may be formed on the substrate layer 102 to reduce a lattice mismatch between the substrate layer 102 and a next layer in the transistor 100. In one aspect, the nucleation layer 136 may be formed directly on the substrate layer 102. In other aspects, the nucleation layer 136 may be formed on the substrate layer 102 with intervening layer(s), such as SiC epitaxial layer(s) formed on a SiC material implementation of the substrate layer 102. The nucleation layer 136 may include different suitable materials, such as a Group III-Nitride material, e.g., AlₓIn_{y1-x-y}GaN (where 0<=x<=1, 0<=y<=1, x+y<=1). The nucleation layer 136 may be formed on the substrate layer 102 using known semiconductor growth techniques such as Metal Oxide Chemical Vapor Deposition (MOCVD), Hydride Vapor Phase Epitaxy (HVPE), Molecular Beam Epitaxy (MBE), and/or the like. In some aspects, the nucleation layer 136 may be AlN or AlGaN, such as undoped AlN or AlGaN.

In some aspects, the channel layer 104 is formed directly on the nucleation layer 136 or on the nucleation layer 136 with intervening layer(s). In some aspects, the channel layer 104 is formed to include the nucleation layer 136. Also, additional layers can be included below or in the channel layer 104 such as a confinement layer, and/or other layers. Depending on the aspect, the channel layer 104 may be formed of different suitable materials such as a Group III-nitride such as AlₓGa_{y}In_{(1-x-y)}N (where 0<=x<=1, 0<=y<=1, x+y<=1), e.g., GaN, Aluminum Gallium Nitride (AlGaN), Aluminum Nitride (AlN), and the like, or another suitable material. In one aspect, the channel layer 104 is formed of GaN. The channel layer 104 or portions thereof may be doped with dopants, such as, Fe and/or C or alternatively can be wholly or partly undoped. In one aspect, the channel layer 104 is directly on the substrate layer 102.

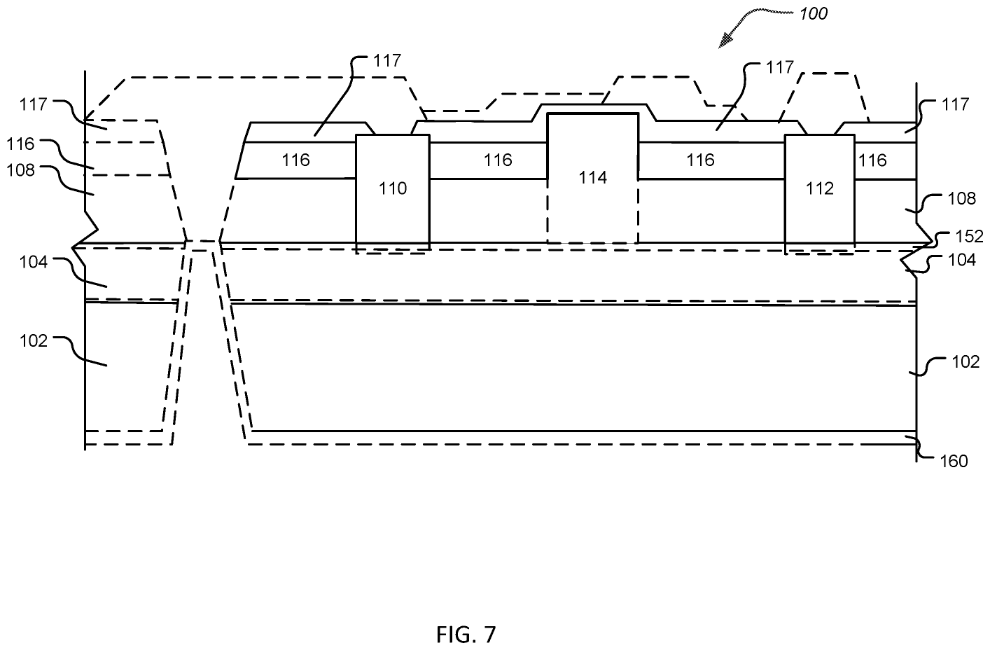

FIG. 7 shows a cross-sectional view of another aspect of a transistor according to FIG. 1 and FIG. 2.

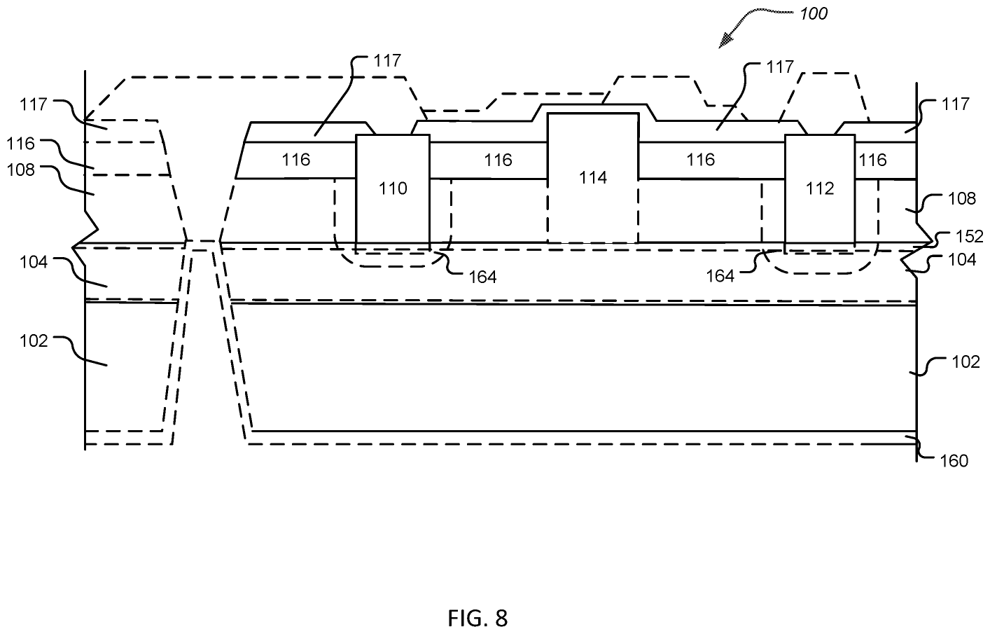

FIG. 8 shows a cross-sectional view of another aspect of a transistor according to FIG. 3 and FIG. 4.

FIG. 7 and FIG. 8 show different aspects and/or features of the transistor 100 of the present disclosure with like reference numerals representing the same or analogous parts in the various aspects and figures of the disclosure. It should be understood that a feature described in one aspect of the disclosure or illustrated in a Figure can be added to another aspect or replace a feature in another aspect. In this regard, the transistor 100 of FIG. 7 and FIG. 8 may further include any one or more other aspects as described herein.

With reference to FIG. 7 and FIG. 8, the transistor 100 may include a spacer layer 117. In some aspects, the spacer layer 117 may be formed on the spacer layer 116 and the gate 114. In one aspect, the spacer layer 116 may be provided on the barrier layer 108. In one aspect, the spacer layer 117 may be provided over the gate 114 and the spacer layer 116. In one aspect, the spacer layer 117 may include a non-conducting material such as a dielectric. In one aspect, the spacer layer 117 may include a number of different layers of dielectrics or a combination of dielectric layers. In one aspect, the spacer layer 117 may be many different thicknesses, with a suitable range of thicknesses being approximately 0.05 to 2 microns. In one aspect, the spacer layer 117 may include a material such as a Group III nitride material having different Group III elements such as alloys of Al, Ga, or In, with a suitable spacer layer material being AlxInyGa1−x−y (where 0<=x<=1 and 0<=y<=1, x+y<=1).

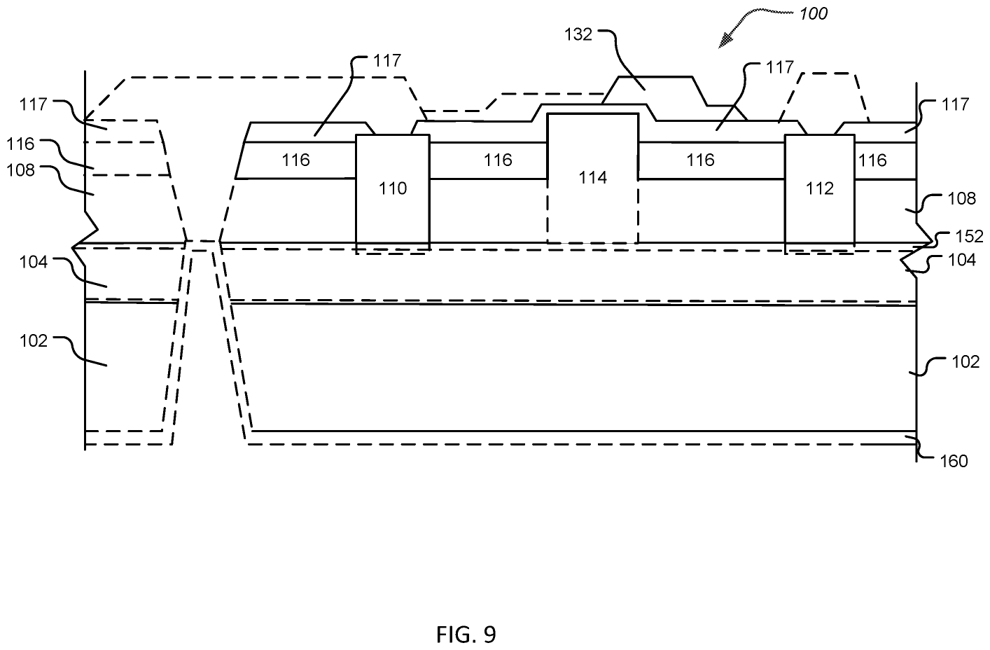

FIG. 9 shows a cross-sectional view of another aspect of a transistor according to FIG. 1 and FIG. 2.

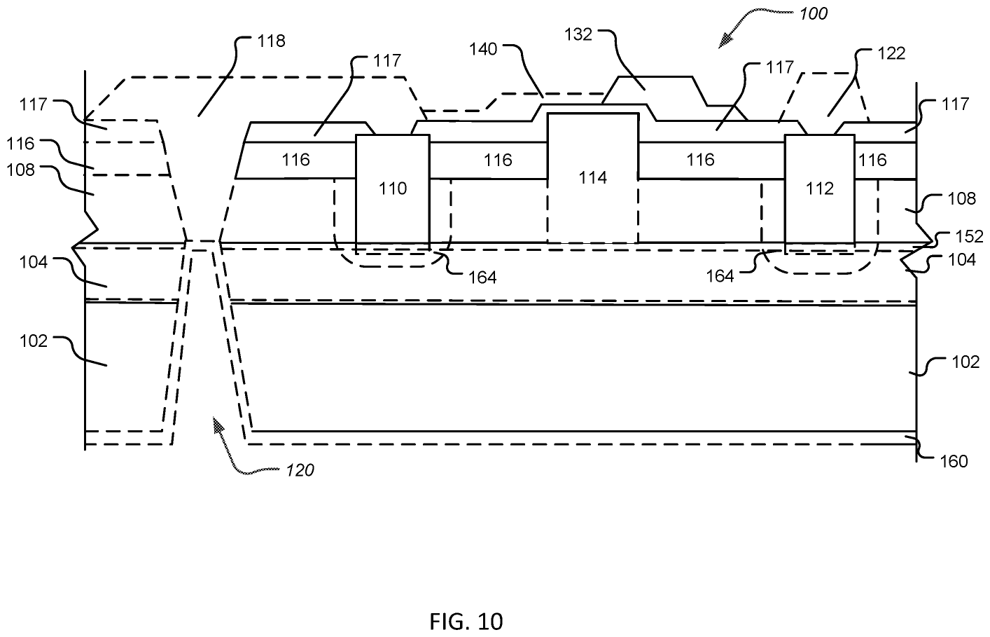

FIG. 10 shows a cross-sectional view of another aspect of a transistor according to FIG. 3 and FIG. 4.

FIG. 9 and FIG. 10 show different aspects and/or features of the transistor 100 of the present disclosure with like reference numerals representing the same or analogous parts in the various aspects and figures of the disclosure. It should be understood that a feature described in one aspect of the disclosure or illustrated in a Figure can be added to another aspect or replace a feature in another aspect. In this regard, the transistor 100 of FIG. 9 and FIG. 10 may further include any one or more other aspects as described herein.

With reference to FIG. 9 and FIG. 10, the transistor 100 may include a field plate 132. In some aspects, the spacer layer 117 may be formed on the spacer layer 116 and the gate 114, and the field plate 132 may be provided on the spacer layer 117.

In other aspects, for example, the spacer layer 116 may be formed on the barrier layer 108 and on the gate 114. In such aspects, the field plate 132 can be formed directly on the spacer layer 116. Other multiple field plate configurations are possible with the field plate 132 overlapping or non-overlapping with the gate 114 and/or multiple field plates 132 being used.

In one aspect, the field plate 132 may be arranged on the spacer layer 117 between the gate 114 and the drain 112. In one aspect, the field plate 132 may be deposited on the spacer layer 117 between the gate 114 and the drain 112. In one aspect, the field plate 132 may be electrically connected to one or more other components in the transistor 100. In one aspect, the field plate 132 may not be electrically connected to any other components of the transistor 100. In some aspects, the field plate 132 may be adjacent the gate 114 and an additional implementation of the spacer layer 117 of dielectric material may be included at least partially over the gate 114 to isolate the gate 114 from the field plate 132. In some aspects, the field plate 132 may overlap the gate 114 and an additional configuration of the spacer layer 117 of dielectric material may be included at least partially over the gate 114 to isolate the gate 114 from the field plate 132.

The field plate 132 may extend different distances from the edge of the gate 114, with a suitable range of distances being approximately 0.1 to 2 microns. In some aspects, the field plate 132 may include many different conductive materials with a suitable material being a metal, or combinations of metals, deposited using standard metallization methods. In one aspect, the field plate 132 may include titanium, gold, nickel, titanium/gold, nickel/gold, or the like.

In one aspect, the field plate 132 may be formed on the spacer layer 117 between the gate 114 and the drain 112, with the field plate 132 being in proximity to the gate 114 but not overlapping the gate 114. In one aspect, a space between the gate 114 and field plate 132 may be wide enough to isolate the gate 114 from the field plate 132, while being small enough to maximize a field effect provided by the field plate 132.

In certain aspects, the field plate 132 may reduce a peak operating electric field in the transistor 100. In certain aspects, the field plate 132 may reduce the peak operating electric field in the transistor 100 and may increase the breakdown voltage of the transistor 100. In certain aspects, the field plate 132 may reduce the peak operating electric field in the transistor 100 and may reduce trapping in the transistor 100. In certain aspects, the field plate 132 may reduce the peak operating electric field in the transistor 100 and may reduce leakage currents in the transistor 100.

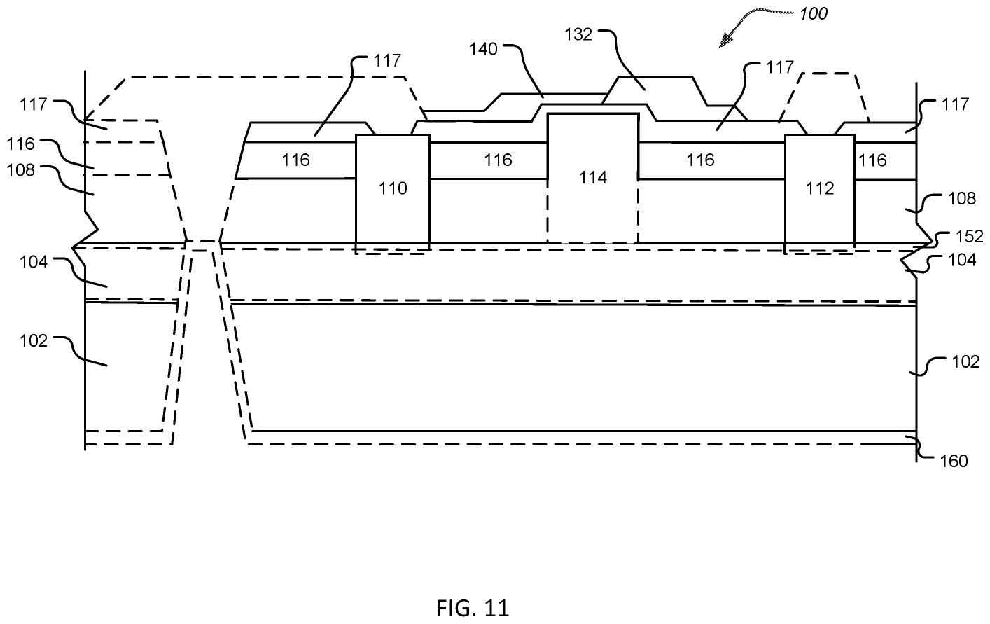

FIG. 11 shows a cross-sectional view of another aspect of a transistor according to FIG. 1 and FIG. 2.

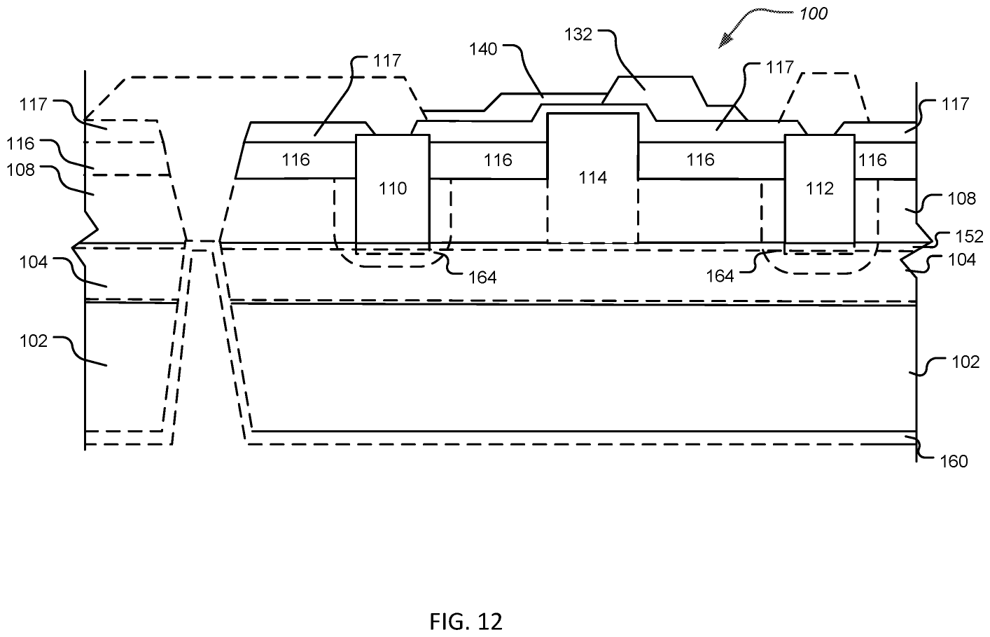

FIG. 12 shows a cross-sectional view of another aspect of a transistor according to FIG. 3 and FIG. 4.

FIG. 11 and FIG. 12 show different aspects and/or features of the transistor 100 of the present disclosure with like reference numerals representing the same or analogous parts in the various aspects and figures of the disclosure. It should be understood that a feature described in one aspect of the disclosure or illustrated in a Figure can be added to another aspect or replace a feature in another aspect. In this regard, the transistor 100 of FIG. 11 and FIG. 12 may further include any one or more other aspects as described herein.

With reference to FIG. 11 and FIG. 12, the transistor 100 may include in certain aspects the field plate 132 as described herein and a connection 140. In this regard, the field plate 132 may be electrically connected to the source 110 through the connection 140. Alternatively, the field plate 132 may be electrically connected to the gate 114 through the connection 140. Alternatively, the field plate 132 may be electrically connected to other portions of the transistor 100 through the connection 140.

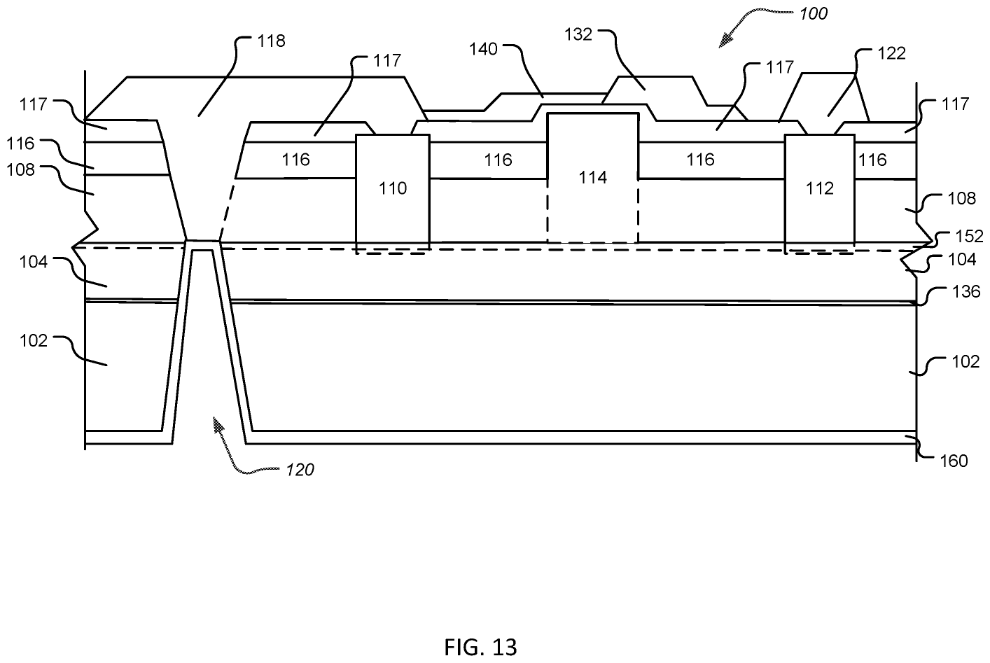

FIG. 13 shows a cross-sectional view of another aspect of a transistor according to FIG. 1 and FIG. 2.

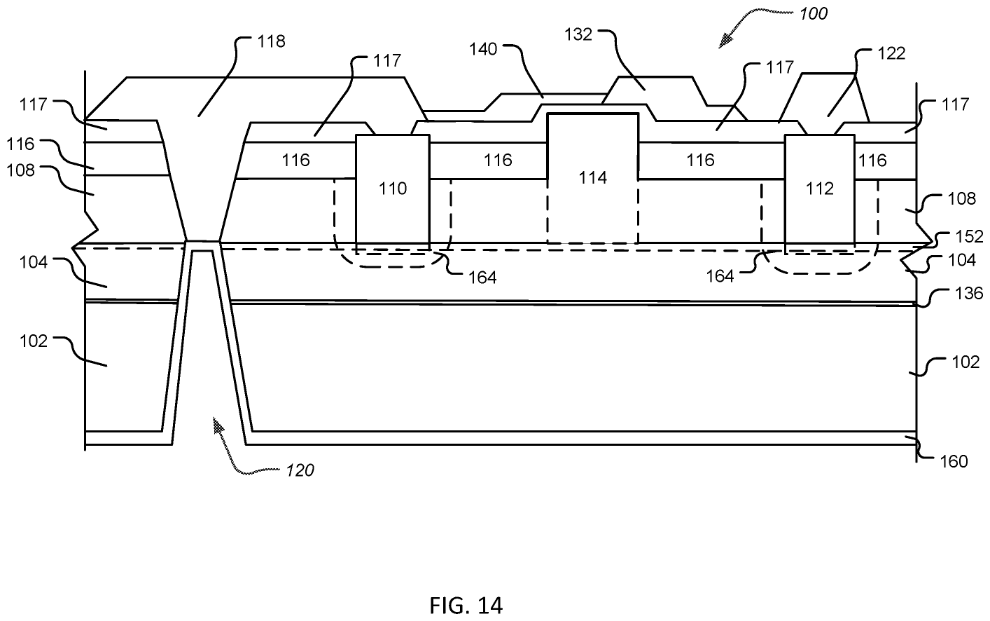

FIG. 14 shows a cross-sectional view of another aspect of a transistor according to FIG. 3 and FIG. 4.

FIG. 13 and FIG. 14 show different aspects and/or features of the transistor 100 of the present disclosure with like reference numerals representing the same or analogous parts in the various aspects and figures of the disclosure. It should be understood that a feature described in one aspect of the disclosure or illustrated in a Figure can be added to another aspect or replace a feature in another aspect. In this regard, the transistor 100 of FIG. 13 and FIG. 14 may further include any one or more other aspects as described herein.

With reference to FIG. 13 and FIG. 14, the transistor 100 may include one or more of a source contact 118, a drain contact 122, a recess 120, and/or a back metal portion 160. In one aspect, the source 110 of the transistor 100 may have the source contact 118. The source contact 118 may be electrically connected to the source 110. The source contact 118 may be arranged at least partially on the spacer layer 117 and/or the spacer layer 116. The source contact 118 may be directly or indirectly connected to the source 110.

In one aspect, the source contact 118 may be formed at least in part in the recess 120. The recess 120 may be provided in the channel layer 104 and/or the barrier layer 108. The recess 120 may extend down to the channel layer 104 and/or the barrier layer 108 to allow for the source contact 118 to be created there. The recess 120 may be formed by etching, and may also use a material to define the recess 120. The material may be removed after the recess 120 has been created. In further aspects, the recess 120 may also include a corresponding recess extending through the substrate layer 102.

In one aspect, the drain 112 of the transistor 100 may have the drain contact 122. The drain contact 122 may be electrically connected to the drain 112. The drain contact 122 may be arranged at least partially on the spacer layer 117 and/or the spacer layer 116. The drain contact 122 may be directly or indirectly connected to the drain 112.

In one aspect, the substrate layer 102 of the transistor 100 may include the back metal portion 160. The back metal portion 160 may be Au, Ag, Al, Pt, Ti, Si, Ni, Al, and/or Copper (Cu). Other suitable highly conductive metals may also be used for the back metal portion 160. In one or more aspects, the back metal portion 160 may electrically couple to the source contact 118. In one or more aspects, the back metal portion 160 may extend into the recess 120 and electrically couple to the source contact 118.

In another aspect, one or more metal overlayers may be provided on one or more of the source 110, the source contact 118, the drain 112, the drain contact 122, and/or the gate 114. The overlayers may be Au, Ag, Al, Pt, Ti, Si, Ni, Al, and/or Copper (Cu). Other suitable highly conductive metals may also be used for the overlayers. In one or more aspects, the metal overlayer may electrically couple to the source contact 118 and/or the drain contact 122. In another aspect, the source 110, the source contact 118, the drain 112, the drain contact 122, and/or the gate 114 may include Au, Ag, Al, Pt, Ti, Si, Ni, Al, and/or Copper (Cu). Other suitable highly conductive metals may also be used.

In aspects of the transistor 100 of the disclosure, the channel layer 104 may include an upper portion of high purity GaN and the channel layer 104 may also include a lower portion that may form an AlGaN back barrier to achieve better electron confinement. In one aspect, the lower portion that forms the back barrier may be AlGaN of n type. The back barrier construction may be implemented in any of the aspects of the disclosure.

In aspects of the transistor 100 of the disclosure, the channel layer 104 may be designed to be of the high purity type where the Fermi level is in the upper half of the bandgap, which minimizes slow trapping effects normally observed in GaN HEMTs. In this regard, the traps under the Fermi level are filled always and thus slow transients may be prevented. In some aspects, the channel layer 104 may be as thin as possible consistent with achieving good crystalline quality. Applicants have already demonstrated 0.4 μm layers with good quality.

In aspects of the transistor 100 of the disclosure, a AlₓIn_{y}Ga_{1-x-y} (where 0<=x<=1 and 0<=y<=1, x+y<=1) nucleation layer 136 or channel layer 104 may be grown on the substrate layer 102 via an epitaxial crystal growth method, such as MOCVD (Metalorganic Chemical Vapor Deposition), HVPE (Hydride Vapor Phase Epitaxy) or MBE (Molecular Beam Epitaxy). The formation of the nucleation layer 136 may depend on the material of the substrate layer 102.

In aspects of the transistor 100 of the disclosure, the channel layer 104 may be formed with Lateral Epitaxial Overgrowth (LEO). LEO can, for example, improve the crystalline quality of GaN layers. When semiconductor layers of a HEMT are epitaxial, the layer upon which each epitaxial layer is grown may affect the characteristics of the device. For example, LEO may reduce dislocation density in epitaxial GaN layers.

In aspects of the transistor 100 of the disclosure, the substrate layer 102 may be silicon carbide and include a carbon face. In one aspect, the substrate layer 102 may be silicon carbide and include a carbon face arranged adjacent the channel layer 104. In one aspect, the substrate layer 102 may be silicon carbide and include a carbon face and the substrate layer 102 may be flipped so as to be arranged adjacent the channel layer 104. In this aspect, the channel layer 104 may be GaN having a nitrogen face adjacent the carbon face of the substrate layer 102. In one aspect, the channel layer 104 may be GaN having alternating GaN and N layers with a N layer and/or a nitrogen face adjacent the carbon face of the substrate layer 102.

In aspects of the transistor 100 of the disclosure, the channel layer 104 may include nonpolar GaN. In one aspect, the channel layer 104 may include semipolar GaN. In one aspect, the channel layer 104 may include hot wall epitaxy. In one aspect, the channel layer 104 may include hot wall epitaxy having a thickness in the range of 0.15 microns to 0.25 microns, 0.2 microns to 0.3 microns, 0.25 microns to 0.35 microns, 0.3 microns to 0.35 microns, 0.35 microns to 0.4 microns, 0.4 microns to 0.45 microns, 0.45 microns to 0.5 microns, 0.5 microns to 0.55 microns, or 0.15 microns to 0.55 microns.

In aspects of the transistor 100 of the disclosure, a gate contact may be provided for the gate 114 in between the source 110 and the drain 112. Furthermore, in certain aspects of the disclosure, the gate contact may be disposed on the barrier layer 108. In one aspect, the gate contact may be disposed directly on the barrier layer 108.

In aspects of the transistor 100 of the disclosure, the gate 114 may be formed of platinum (Pt), nickel (Ni), and/or gold (Au), however, other metals known to one skilled in the art to achieve the Schottky effect, may be used. In one aspect, the gate 114 may include a Schottky gate contact that may have a three-layer structure. Such a structure may have advantages because of the high adhesion of some materials. In one aspect, the gate 114 may further include an overlayer of highly conductive metal. In one aspect, the gate 114 may be configured as a T-shaped gate.

In aspects of the transistor 100 of the disclosure, the contacts of the source 110, the gate 114, and/or the drain 112 may include Al, Ti, Si, Ni, and/or Pt. In some aspects, the source contact 118 may include Al, Ti, Si, Ni, and/or Pt. In particular aspects, the material of the contacts of the source 110, the gate 114, and/or the drain 112 may be the same material as the source contact 118. In this aspect, utilizing the same material may be beneficial in that manufacturing may be easier, simplified, and/or less costly. In other aspects, the material of the contacts of the source 110, the gate 114, the drain 112, and the source contact 118 may be different.

In the aspects of the disclosure, the heterointerface 152 may be between the barrier layer 108 and the channel layer 104. In one aspect, the source 110 and the drain 112 electrodes may be formed making ohmic contacts such that an electric current flows between the source 110 and the drain 112 electrodes via a two-dimensional electron gas (2DEG) induced at the heterointerface 152 between the channel layer 104 and the barrier layer 108 when a gate 114 electrode is biased at an appropriate level. In one aspect, the heterointerface 152 may be in the range of 0.005 μm to 0.007 μm, 0.007 μm to 0.009 μm, and 0.009 μm to 0.011 μm.

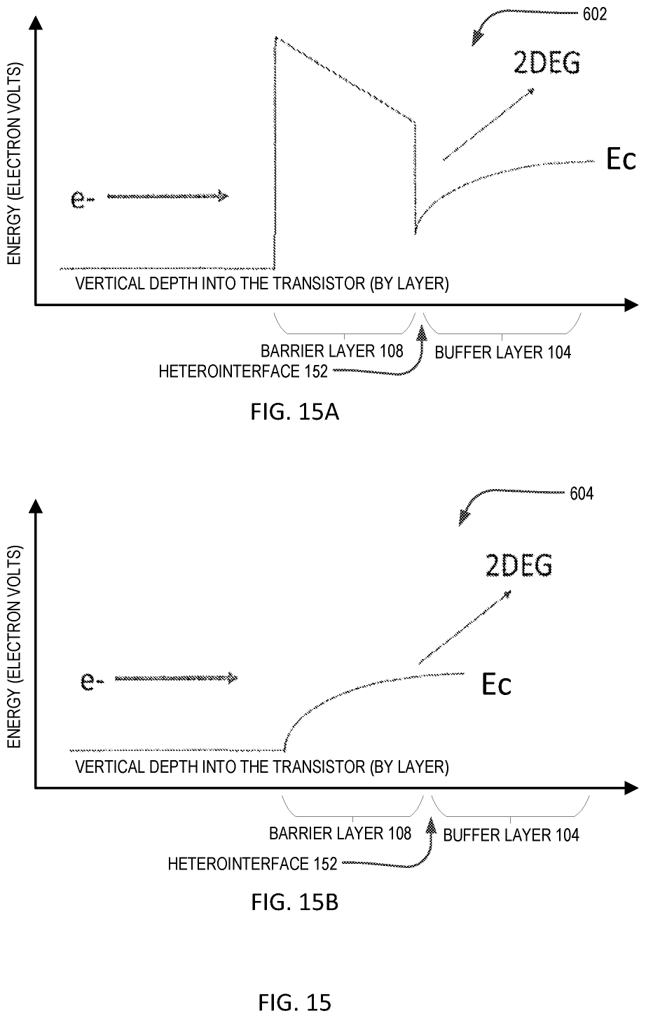

FIG. 15 includes FIG. 15A and FIG. 15B graphically illustrating resistance within transistors.

In particular, FIG. 15A illustrates a graph 602 implementing a source and drain in a typical implementation; and FIG. 15B illustrates a graph 604 implementing the source 110 and the drain 112 consistent with the transistor 100 of the disclosure. With reference to FIG. 15A and FIG. 15B, the graph 602 and the graph 604 are illustrated with a first axis indicative of energy (electron volts); and a second axis that is indicative of a vertical depth into the transistor indexed with respect to transistor layers.

In this regard, the origin of the graph 602 and the graph 604 being associated with an upper surface of the transistor 100 and the depth along this axis being indicative of the depth from the upper surface to a particular layer within the transistor as labeled in the graph 602 and the graph 604. In particular, the vertical depth into the transistor is indicated with respect to the barrier layer 108, the heterointerface 152, and the channel layer 104.

Additionally, with reference to FIG. 15, the graph 604 and the graph 602 include a trace Ec—electrical conduction. As can be realized by comparing the graph 602 to the graph 604, the configuration and arrangements of the source 110 and drain 112 of the disclosure results in a substantially reduced ON-state resistance RDS(on) as illustrated by a lower rise of the graph 604 in comparison to the graph 602. In particular, the graph 604 illustrates a reduced ON-state resistance RDS(on) that may be reduced by 4%-40%, 4%-8%, 8%-12%, 12%-16%, 16%-20%, 20%-24%, 24%-28%, 28%-32%, 32%-36%, or 36%-40%.

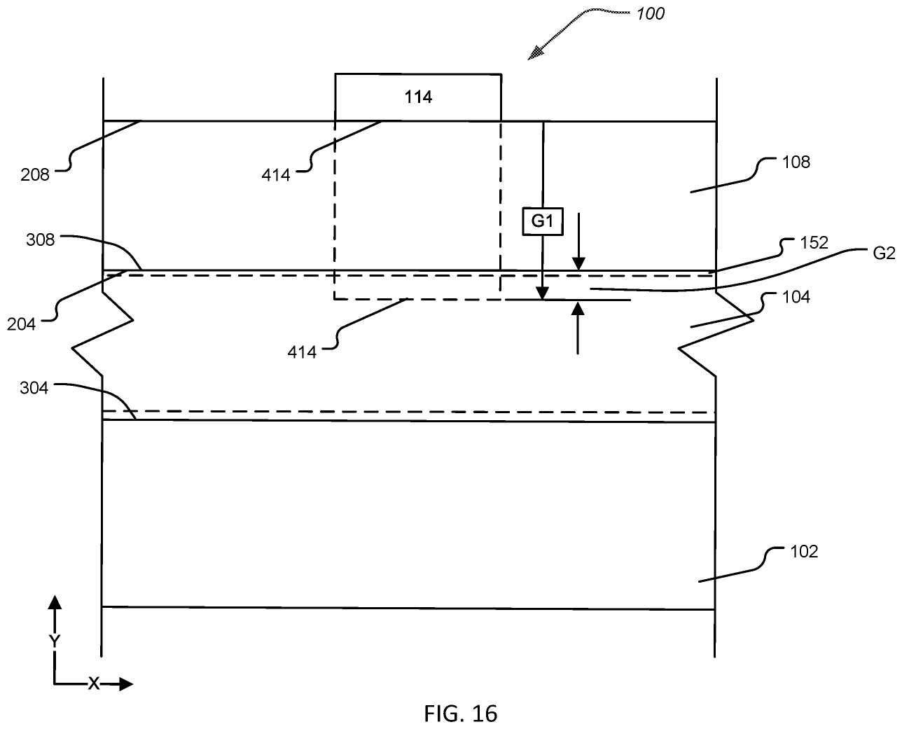

FIG. 16 shows a detailed partial cross-sectional view of the transistor of FIG. 1 and/or FIG. 3.

In particular, FIG. 16 illustrates further details of the structural configuration and arrangement of the gate 114. With reference to FIG. 16, the gate 114 may be formed on the barrier layer 108, within the barrier layer 108, on the channel layer 104, and/or in the channel layer 104. In one aspect, the gate 114 may be formed on the barrier layer 108. The gate 114 may be arranged directly on the barrier layer 108 or the gate 114 may be arranged on intervening layer(s) on the barrier layer 108, such as an AlGaN layer on an AlN barrier layer. Other or additional intervening layers are possible. In some aspects, the gate 114 may be deposited in a channel formed in the spacer layer 116, for example, a channel formed by etching or the like using semiconductor processing techniques understood by those of ordinary skill in the art. The gate 114 may have a T-shaped cross-section. Other gate configurations, gate shapes, and/or the like are contemplated by this disclosure for implementation as the gate 114.

In one aspect, the gate 114 may be structured and arranged to extend partially through the barrier layer 108, the gate 114 may be structured and arranged to extend completely through the barrier layer 108, the gate 114 may be structured and arranged to extend completely through the barrier layer 108 to the heterointerface 152, and/or the gate 114 may be structured and arranged to extend completely through the barrier layer 108 and extend partially through the channel layer 104.

In one aspect, the gate 114 may be structured and arranged to extend vertically along the y-axis through the upper surface 208 of the barrier layer 108 and partially through the barrier layer 108 towards the lower surface 308 of the barrier layer 108.

In one aspect, the gate 114 may be structured and arranged to extend vertically along the y-axis through the upper surface 208 of the barrier layer 108, through the barrier layer 108, and to the lower surface 308 of the barrier layer 108.

In one aspect, the gate 114 may be structured and arranged to extend vertically along the y-axis through the upper surface 208 of the barrier layer 108, through the barrier layer 108, and through the lower surface 308 of the barrier layer 108.

In one aspect, the gate 114 may be structured and arranged to extend vertically along the y-axis through the upper surface 208 of the barrier layer 108, through the barrier layer 108, through the lower surface 308 of the barrier layer 108, and through the upper surface 204 of the channel layer 104.

In one aspect, the gate 114 may be structured and arranged to extend vertically along the y-axis through the upper surface 208 of the barrier layer 108, through the barrier layer 108, through the lower surface 308 of the barrier layer 108, and through the upper surface 204 of the channel layer 104.

In one aspect, the gate 114 may be structured and arranged to extend vertically along the y-axis through the upper surface 208 of the barrier layer 108, through the barrier layer 108, through the lower surface 308 of the barrier layer 108, through the upper surface 204 of the channel layer 104, and partially through the channel layer 104.

With further reference to FIG. 16, a depth that the gate 114 is structurally arranged and configured within the transistor 100 is illustrated with respect to a distance G1 along the y-axis or vertical axis. The distance G1 being defined as a percentage of the thickness of the barrier layer 108. In one or more aspects, the distance G1 may be 80% to 120% of the thickness of the barrier layer 108, 80% to 90% of the thickness of the barrier layer 108, 90% to 95% of the thickness of the barrier layer 108, 95% to 99% of the thickness of the barrier layer 108, 99% to 100% of the thickness of the barrier layer 108, 100% to 101% of the thickness of the barrier layer 108, 99% to 101% of the thickness of the barrier layer 108, 101% to 102% of the thickness of the barrier layer 108, 102% to 105% of the thickness of the barrier layer 108, 105% to 110% of the thickness of the barrier layer 108, or 110% to 120% of the thickness of the barrier layer 108. In this regard, distances greater than 100% are indicative of distances into the channel layer 104.

In one aspect, the gate 114 may be structured and arranged to extend vertically along the y-axis through the barrier layer 108 and partially through the channel layer 104 a distance G2. In one aspect, the distance G2 may be 50 Å-1000 Å, 50 Å-150 Å, 150 Å-250 Å, 250 Å-500 Å, 500 Å-800 Å, or 800 Å-1000 Å. In one aspect, the distance G2 may be defined as a percentage of the thickness of the channel layer 104. In one or more aspects, the distance G2 may be 1% to 10%, 1% to 2%, 2% to 3%, 3% to 4%, 4% to 5%, 5% to 6%, 6% to 7%, 7% to 8%, 8% to 9%, or 9% to 10%, of the thickness of the channel layer 104.

In one aspect, the gate 114 may be structured and arranged to have a lower surface 414 as illustrated in FIG. 16. The lower surface 414 of the gate 114 may extend generally parallel to one or more of the upper surface 208, the lower surface 308, the upper surface 204, and/or the lower surface 304. In this regard, generally is defined as being within 1°-20°.

In one aspect, the lower surface 414 of the gate 114 may be vertically below (along the y-axis) the upper surface 208, may be within the barrier layer 108, may be on the lower surface 308, may be directly on the lower surface 308, may be within the lower surface 308, may be vertically below the lower surface 308, may be on the upper surface 204, may be directly on the upper surface 204, may be within the upper surface 204, may be vertically below the upper surface 204, may be on the heterointerface 152, may be directly on the heterointerface 152, may be vertically below the heterointerface 152, may be within the heterointerface 152, and/or may be within the channel layer 104.

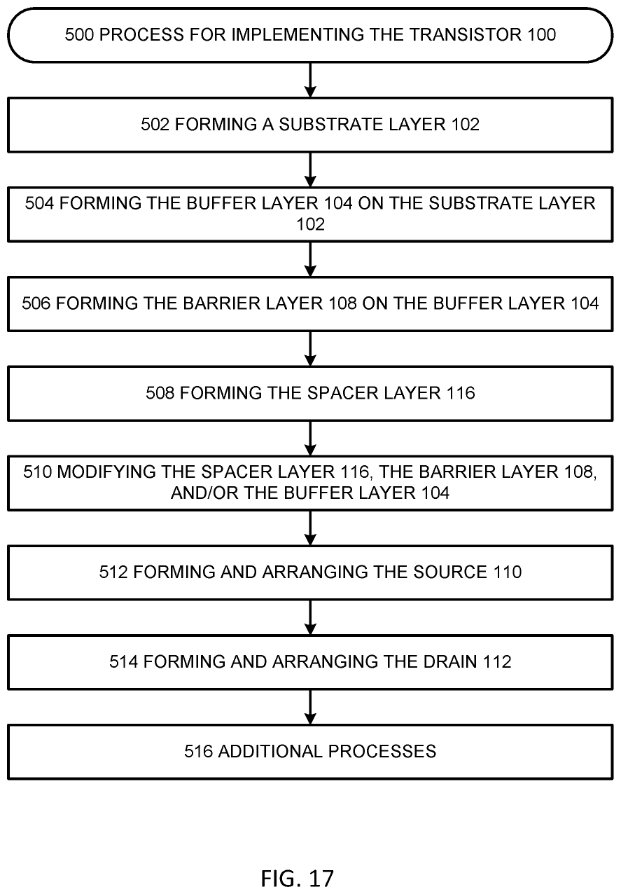

FIG. 17 shows a process of implementing a transistor according to the disclosure.

In particular, FIG. 17 shows an exemplary process for implementing the transistor 100 (box 500) of the disclosure. In particular, it should be noted that the process for implementing the transistor 100 (box 500) is merely exemplary and may be modified consistent with the various aspects disclosed herein. Moreover, the process for implementing the transistor 100 (box 500) of the disclosure may include a process of manufacturing the transistor 100. It should be noted that the process for implementing the transistor 100 (box 500) may be performed in a different order consistent with the aspects described above. Moreover, the process for implementing the transistor 100 (box 500) may be modified to have more or fewer process steps consistent with the various aspects disclosed herein.

The process for implementing the transistor 100 (box 500) of the disclosure may begin by forming a substrate layer 102 (box 502). In this regard, the forming a substrate layer 102 (box 502) may include any one or more materials, structures, arrangements, processes, and/or the like of the substrate layer 102 as described herein. Moreover, one or more proceeding or subsequent processes may also be implemented consistent with the disclosure.

The substrate layer 102 may be made of Silicon Carbide (SiC). In some aspects, the substrate layer 102 may be a semi-insulating SiC substrate, a p-type substrate, an n-type substrate, and/or the like. In some aspects, the substrate layer 102 may be very lightly doped. In one aspect, the background impurity levels may be low. In one aspect, the background impurity levels may be 1E15/cm³ or less. The substrate layer 102 may be formed of SiC selected from the group of 6H, 4H, 15R, 3C SiC, or the like. In another aspect, the substrate layer 102 may be GaAs, GaN, or other material suitable for the applications described herein. In another aspect, the substrate layer 102 may include sapphire, spinel, ZnO, silicon, or any other material capable of supporting growth of Group III-nitride materials.

The process for implementing the transistor 100 (box 500) of the disclosure may include forming the channel layer 104 on the substrate layer 102 (box 504). In this regard, the forming the channel layer 104 on the substrate layer 102 (box 504) may include any one or more materials, structures, arrangements, processes, and/or the like of the channel layer 104 as described herein. Moreover, one or more proceeding or subsequent processes may also be implemented consistent with the disclosure.

The channel layer 104 may be grown or deposited on the substrate layer 102. In one aspect, the channel layer 104 may be GaN. In another aspect, the channel layer 104 may be formed with LEO. In one aspect, a nucleation layer 136 may be formed on the substrate layer 102 and the channel layer 104 may be formed on the nucleation layer 136. The channel layer 104 may be grown or deposited on the nucleation layer 136. In one aspect, the channel layer 104 may be GaN. In another aspect, the channel layer 104 may be formed with LEO.

The process for implementing the transistor 100 (box 500) of the disclosure may include forming the barrier layer 108 on the channel layer 104 (box 506). In this regard, the forming the barrier layer 108 on the channel layer 104 (box 506) may include any one or more materials, structures, arrangements, processes, and/or the like of the barrier layer 108 as described herein. Moreover, one or more proceeding or subsequent processes may also be implemented consistent with the disclosure.

The barrier layer 108 may be an n-type conductivity layer or may be undoped. In one aspect, the barrier layer 108 may be AlGaN. The barrier layer 108 may be formed on the channel layer 104. In one aspect, the barrier layer 108 may be formed directly on the channel layer 104, and in other aspects, the barrier layer 108 is formed on the channel layer 104 with intervening layer(s). Depending on the aspect, the channel layer 104 may be formed of different suitable materials such as a Group III-nitride such as AlₓGa_{y}In_{(1-x-y)}N (where 0<=x<=1, 0<=y<=1, x+y<=1), e.g., AlGaN, AlN, or InAlGaN, or another suitable material. In one aspect, the barrier layer 108 may be AlGaN, and in another aspect the barrier layer 108 is AlN. In one aspect, the barrier layer 108 may be undoped. In one aspect, the barrier layer 108 may be doped. In one aspect, the barrier layer 108 may be an n-type material. In some aspects, the barrier layer 108 may have multiple layers of n-type material having different carrier concentrations. In one aspect, the barrier layer 108 may be a Group III-nitride or a combination thereof. In one aspect, a bandgap of the channel layer 104 may be less than a bandgap of the barrier layer 108 to form a two-dimensional electron gas (2DEG) at a heterointerface 152 between the channel layer 104 and barrier layer 108 when biased at an appropriate level. In one aspect, a bandgap of the channel layer 104 that may be GaN may be less than a bandgap of the barrier layer 108 that may be AlGaN to form the two-dimensional electron gas (2DEG) at a heterointerface 152 between the channel layer 104 and barrier layer 108 when biased at an appropriate level.

The process for implementing the transistor 100 (box 500) of the disclosure may include forming the spacer layer 116 (box 508). In this regard, the forming the spacer layer 116 (box 508) may include any one or more materials, structures, arrangements, processes, and/or the like of the spacer layer 116 as described herein. Moreover, one or more proceeding or subsequent processes may also be implemented consistent with the disclosure.

The spacer layer 116 may be a passivation layer, such as SiN, AlO, SiO, SiO₂, AlN, or the like, or a combination incorporating multiple layers thereof, which may be deposited over the exposed surface of the barrier layer 108.

The process for implementing the transistor 100 (box 500) of the disclosure may include modifying the spacer layer 116, the barrier layer 108, and/or the channel layer 104 (box 510). In this regard, the modifying the spacer layer 116, the barrier layer 108, and/or the channel layer 104 (box 510) may include any one or more materials, structures, arrangements, processes, and/or the like as described herein. Moreover, one or more proceeding or subsequent processes may also be implemented consistent with the disclosure.

In one aspect, with reference to FIG. 3 and FIG. 4, the transistor 100 may be configured such that the barrier layer 108 may include a region 164 under and/or adjacent the source 110 and/or the drain 112. In one aspect, a mask may be formed on the spacer layer 116. The mask may include photoresist or any other suitable mask material, such as SiN and/or SiO₂. The mask may have a thickness selected to block implanted ions. For example, when the spacer layer 116 includes SiN, the mask may include an oxide such as SiO₂, and vice-versa.

Windows may be opened in the mask to expose surface portions of the spacer layer 116, and ions may be implanted through the windows into the spacer layer 116 such that at least a portion of the implanted ions are implanted through the spacer layer 116 and come to rest within the barrier layer 108 and/or within the channel layer 104. The implanted ions may form a distribution profile having a peak dopant concentration in the barrier layer 108 and/or the channel layer 104. Accordingly, a region 164 may be formed extending through the barrier layer 108 and/or the channel layer 104.

The implant conditions may be selected to provide a distribution of implanted dopants having a substantially uniform concentration throughout the region 164 of the barrier layer 108 and/or the channel layer 104. For instance, the implant process may include multiple implant steps to provide a relatively uniform profile of implanted dopants throughout the region 164. As such, the number of implant steps may depend on the thickness of the spacer layer 116, the barrier layer 108, and/or the channel layer 104 so that the region 164 may contact the channel layer 104. For example, the implant process may include a first implant step performed under a first set of implant conditions, and a subsequent implant step performed under a second set of implant conditions. However, more than two implant steps may be performed to provide a region 164 having a substantially uniform dopant concentration.

After formation of the regions 164, the implants may be activated by an activation anneal. In this regard, the mask may be removed prior to the implant activation anneal, for example, by means of a photoresist strip and/or an etch process. However, the activation anneal may be performed with the spacer layer 116 in place. In particular, the spacer layer 116 may protect the barrier layer 108 during the anneal. In some embodiments, the spacer layer 116 may further remain on the barrier layer 108 to act as a passivation layer for the barrier layer 108 in the completed device.

The activation anneal may be performed in an inert atmosphere. The activation anneal may be performed at a temperature sufficient to activate the implanted dopant ions but less than a temperature at which the underlying semiconductor layer, i.e., the barrier layer 108, deteriorates. The presence of the spacer layer 116 during the high temperature process steps may inhibit damage to the underlying epitaxial layers, including the barrier layer 108, that may otherwise result from high temperature annealing.

In one or more aspects, the source 110 may be formed and/or defined by an open area in the spacer layer 116, the barrier layer 108, and/or the channel layer 104 for placement of the source 110. The open area may be part of an ohmic window etch process. In this regard, the modifying the spacer layer 116, the barrier layer 108, and/or the channel layer 104 (box 510) may include modifying utilizing an ohmic window etching process. In this regard, the process may include etching through one or more of the spacer layer 116, the barrier layer 108, and/or the channel layer 104.

In one or more aspects, the drain 112 may be formed and/or defined by an open area in the spacer layer 116, the barrier layer 108, and/or the channel layer 104 for placement of the drain 112. The open area may be part of an ohmic window etch process. In this regard, the modifying the spacer layer 116, the barrier layer 108, and/or the channel layer 104 (box 510) may include modifying utilizing an ohmic window etching process. In this regard, the process may include etching through one or more of the spacer layer 116, the barrier layer 108, and/or the channel layer 104.

In one aspect, a mask may be formed on the spacer layer 116, and windows may be opened in the spacer layer 116. The windows may be formed utilizing a low damage etch with respect to the barrier layer 108 and/or the channel layer 104. Examples of low damage etch techniques include etching techniques other than reactive ion etching, such as inductively coupled plasma or electron cyclotron resonance (ECR) or downstream plasma etching with no DC component to the plasma. For an SiO₂ spacer layer 116, a low damage etch may be a wet etch with buffered hydrofluoric acid. A selective etch of SiN and/or SiO₂ to an etch stop layer, followed by a low damage removal of the etch stop layer may also be performed. For a SiN spacer layer 116, SiO₂ may be used as an etch stop layer. In such embodiments, the spacer layer 116 may include the SiN and/or SiO₂ layer as well as the etch stop layer. Thus, the spacer layer 116 may include multiple layers.

The process for implementing the transistor 100 (box 500) of the disclosure may include forming and arranging the source 110 (box 512). In this regard, the forming and arranging the source 110 (box 512) may include any one or more materials, structures, arrangements, processes, and/or the like of the source 110 as described herein. Moreover, one or more proceeding or subsequent processes may also be implemented consistent with the disclosure.

The forming and arranging the source 110 (box 512) may include utilizing a self-aligned ohmic evaporation process. More specifically, an evaporation of the ohmic metal contacts and a solvent-based liftoff. Accordingly, the source 110 may be arranged and/or situated consistent with the disclosure as described herein.

The source 110 may be an ohmic contact of a suitable material that may be annealed. For example, the source 110 may be annealed at a temperature of from about 500° C. to about 800° C. for about 2 minutes. However, other times and temperatures may also be utilized. Times from about 30 seconds to about 10 minutes may be, for example, acceptable. In some aspects, the source 110 may include Al, Ti, Si, Ni, and/or Pt.

The process for implementing the transistor 100 (box 500) of the disclosure may include forming and arranging the drain 112 (box 514). In this regard, the forming and arranging the drain 112 (box 514) may include any one or more materials, structures, arrangements, processes, and/or the like of the drain 112 as described herein. Moreover, one or more proceeding or subsequent processes may also be implemented consistent with the disclosure.

The forming and arranging the drain 112 (box 514) may include utilizing a self-aligned ohmic evaporation process. More specifically, an evaporation of the ohmic metal contacts and a solvent-based liftoff. Accordingly, the drain 112 may be arranged and/or situated consistent with the disclosure as described herein.

In this regard, the drain 112 may be arranged on the barrier layer 108. Like the source 110, the drain 112 may be an ohmic contact of Ni or another suitable material and may also be annealed in a similar fashion. In one aspect, an n+ implant may be used in conjunction with the barrier layer 108 and the contacts are made to the implant.

In one aspect, a region 164 under the drain 112 that is a N+ material may be formed in the barrier layer 108. In one aspect, a region 164 under the drain 112 may be Si doped. In one aspect, there is no formation of a region 164 under the drain 112.

The process for implementing the transistor 100 (box 500) of the disclosure may include additional processes (box 516). The additional processes (box 516) may include arranging the gate 114 on the barrier layer 108 between the source 110 and the drain 112. A layer of Ni, Pt, AU, or the like may be formed for the gate 114 by evaporative deposition or another technique. The gate structure may then be completed by deposition of Pt and Au, or other suitable materials. In some aspects, the contacts of the gate 114 may include Al, Ti, Si, Ni, and/or Pt.

The additional processes (box 516) may include forming the source contact 118 and the drain contact 122. In particular, nickel or another suitable material may be annealed to form an ohmic contact, for example. In some aspects, the contacts of the source contact 118 and the drain contact 122 may include Al, Ti, Si, Ni, and/or Pt. Such a deposition and annealing process may be carried out utilizing conventional techniques known to those of skill in the art. For example, an ohmic contact for the source contact 118 may be annealed at a temperature of from about 600° C. to about 1050° C.

The source 110 and the drain 112 electrodes may be formed making ohmic contacts such that an electric current flows between the source 110 and drain 112 electrodes via a two-dimensional electron gas (2DEG) induced at the heterointerface 152 between the channel layer 104 and barrier layer 108 when a gate 114 electrode is biased at an appropriate level. In one aspect, the heterointerface 152 may be in the range of 0.005 μm to 0.007 μm, 0.007 μm to 0.009 μm, and 0.009 μm to 0.011 μm.

The gate 114 may extend on top of a spacer or the spacer layer 116. The spacer layer 116 may be etched and the gate 114 deposited such that the bottom of the gate 114 is on the surface of barrier layer 108. The metal forming the gate 114 may be patterned to extend across spacer layer 116 so that the top of the gate 114 forms a field plate 132.

The additional processes (box 516) may include forming a field plate 132 that may be arranged on top of another spacer layer 117 that may be separated from the gate 114. In one aspect, the field plate 132 may be deposited on the spacer layer 117 between the gate 114 and the drain 112. In some aspects, the field plate 132 may include many different conductive materials with a suitable material being a metal, or combinations of metals, deposited using standard metallization methods. In one aspect, the field plate 132 may include titanium, gold, nickel, titanium/gold, nickel/gold, or the like. In one aspect, the connection 140 may be formed with the field plate 132 during the same manufacturing step. In one aspect, a plurality of the field plates 132 may be used. In one aspect, a plurality of the field plates 132 may be used and each of the plurality of field plates 132 may be stacked with a dielectric material therebetween. In one aspect, the field plate 132 extends toward the edge of gate 114 towards the drain 112. In one aspect, the field plate 132 extends towards the source 110. In one aspect, the field plate 132 extends towards the drain 112 and towards the source 110. In another aspect, the field plate 132 does not extend toward the edge of gate 114. Finally, the structure may be covered with a dielectric spacer layer such as silicon nitride. The dielectric spacer layer may also be implemented similar to the spacer layer 116. Moreover, it should be noted that the cross-sectional shape of the gate 114, shown in the Figures is exemplary. For example, the cross-sectional shape of the gate 114 in some aspects may not include the T-shaped extensions. Other constructions of the gate 114 may be utilized.

The additional processes (box 516) may include forming the connection 140 may be formed (see FIG. 13). In some aspects, the field plate 132 may be electrically connected to the source 110 with the connection 140. In one aspect, the connection 140 may be formed on the spacer layer 117 to extend between the field plate 132 and the source 110.

Accordingly, the disclosure has provided various structures, arrangements, and/or processes for reducing ON-state resistance RDS(on) that may be implemented in Group III-Nitride based high-electron mobility transistors (HEMTs). However, the disclosed structures, arrangements, and/or processes may be implemented in other types of transistor types. Moreover, the disclosure has provided various structures and arrangements for reducing ON-state resistance RDS(on) that can reduce conduction losses, reduce switching losses, increase current carrying capability, and/or improve other performance characteristics. The disclosed structure can be readily fabricated with currently available techniques such as a high capacity/high volume manufacturing (HVM) tool.

According to further aspects of this disclosure, transistors, such as GaN HEMTs, fabricated on high resistivity substrates may be utilized for high power RF (radio frequency) amplifiers, for high power radiofrequency (RF) applications, and also for low frequency high power switching applications. The advantageous electronic and thermal properties of GaN HEMTs also make them very attractive for switching high power RF signals. In this regard, the disclosure has described a structure with a buried p-layer under the source region to obtain high breakdown voltage in HEMTs for various applications including power amplifiers while at the same time eliminating drifts in device characteristics arising from trapping in the buffer and/or semi-insulating substrates. Use of buried p-layers may also be important in HEMTs for RF switches to obtain high breakdown voltage and good isolation between the input and output.

In particular aspects, the transistor 100 of the disclosure may be utilized in wireless base stations that connect to a wireless device. In further aspects, the transistor 100 of the disclosure may be utilized in amplifiers implemented by wireless base stations that connect to a wireless device. In further aspects, the transistor 100 of the disclosure may be utilized in wireless devices. In further aspects, the transistor 100 of the disclosure may be utilized in amplifiers implemented in wireless devices.

In this disclosure it is to be understood that reference to a wireless device is intended to encompass electronic devices such as mobile phones, tablet computers, gaming systems, MP3 players, personal computers, PDAs, user equipment (UE), and the like. A “wireless device” is intended to encompass any compatible mobile technology computing device that can connect to a wireless communication network, such as mobile phones, mobile equipment, mobile stations, user equipment, cellular phones, smartphones, handsets, wireless dongles, remote alert devices, Internet of things (IoT) based wireless devices, or other mobile computing devices that may be supported by a wireless network. The wireless device may utilize wireless communication technologies like GSM, CDMA, wireless local loop, Wi-Fi, WiMAX, other wide area network (WAN) technology, 3G technology, 4G technology, 5G technology, LTE technology, and/or the like.

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure.

What is claimed is:

1. A high-electron mobility transistor (HEMT) comprising:
a substrate;
a group III-Nitride channel layer on the substrate;
a group III-Nitride barrier layer on the group III-Nitride channel layer, the group III-Nitride barrier layer comprising a higher bandgap than a bandgap of the group III-Nitride channel layer;
a source electrically coupled to the group III-Nitride barrier layer;
a gate electrically coupled to the group III-Nitride barrier layer; and
a drain electrically coupled to the group III-Nitride barrier layer,
wherein at least one of the source and the drain are structured and arranged to extend through the group III-Nitride barrier layer and into the group III-Nitride channel layer.

2. The high-electron mobility transistor (HEMT) of claim 1, wherein:
the source is structured and arranged to extend at least through the group III-Nitride barrier layer and into the group III-Nitride channel layer toward a heterointerface; and
the drain is structured and arranged to extend at least through the group III-Nitride barrier layer and into the group III-Nitride channel layer toward the heterointerface.

3. The high-electron mobility transistor (HEMT) of claim 1, wherein:
the source is structured and arranged to extend at least through the group III-Nitride barrier layer and into the group III-Nitride channel layer to a heterointerface; and
the drain is structured and arranged to extend at least through the group III-Nitride barrier layer and into the group III-Nitride channel layer to the heterointerface.

4. The high-electron mobility transistor (HEMT) of claim 1, wherein:
the group III-Nitride barrier layer includes an upper surface and a lower surface;
the source is structured and arranged to extend vertically through the upper surface of the group III-Nitride barrier layer, through the lower surface of the group III-Nitride barrier layer, and through an upper surface of the group III-Nitride channel layer; and
the drain is structured and arranged to extend vertically through the upper surface of the group III-Nitride barrier layer, through the lower surface of the group III-Nitride barrier layer, and through an upper surface of the group III-Nitride channel layer.

5. The high-electron mobility transistor (HEMT) of claim 4, wherein:
the source is structured and arranged to extend vertically through the upper surface of the group III-Nitride barrier layer, through the group III-Nitride barrier layer, through an upper surface of the group III-Nitride channel layer, and to a heterointerface; and
the drain is structured and arranged to extend vertically through the upper surface of the group III-Nitride barrier layer, through the group III-Nitride barrier layer, through an upper surface of the group III-Nitride channel layer, and to the heterointerface.

6. The high-electron mobility transistor (HEMT) of claim 1, wherein:
the gate is structured and arranged to extend at least partially through the group III-Nitride barrier layer.

7. The high-electron mobility transistor (HEMT) of claim 1, wherein:
the source is structurally arranged and configured to have a vertical depth of 90% to 110% of a thickness of the group III-Nitride barrier layer; and
the drain is structurally arranged and configured to have a vertical depth of 90% to 110% of a thickness of the group III-Nitride barrier layer.

8. The high-electron mobility transistor (HEMT) of claim 1, wherein:
the group III-Nitride barrier layer includes an upper surface and a lower surface;
the source is structured and arranged to have a lower surface;
the drain is structured and arranged to have a lower surface;
the lower surface of the source is vertically below the lower surface of the group III-Nitride barrier layer; and
the lower surface of the drain is vertically below the lower surface of the group III-Nitride barrier layer.

9. The high-electron mobility transistor (HEMT) of claim 8, wherein:
the lower surface of the source is on a heterointerface; and
the lower surface of the drain is on the heterointerface.

10. The high-electron mobility transistor (HEMT) of claim 8, wherein:
the lower surface of the source is within a heterointerface; and
the lower surface of the drain is within the heterointerface.

11. The high-electron mobility transistor (HEMT) of claim 1, further comprising a field plate.

12. The high-electron mobility transistor (HEMT) of claim 1, wherein a structural arrangement and configuration of the source and the drain reduces ON-state resistance RDS(on) by 4%-40%.

13. A process of implementing a high-electron mobility transistor (HEMT) comprising:
providing a substrate;
providing a group III-Nitride channel layer on the substrate;
providing a group III-Nitride barrier layer on the group III-Nitride channel layer, the group III-Nitride barrier layer comprising a higher bandgap than a bandgap of the group III-Nitride channel layer;
electrically coupling a gate to the group III-Nitride barrier layer; and
modifying the group III-Nitride barrier layer and arranging at least one of a source and a drain to extend through the group III-Nitride barrier layer and into the group III-Nitride channel layer.

14. The process of implementing a high-electron mobility transistor (HEMT) of claim 13, further comprising:
forming the source to extend at least through the group III-Nitride barrier layer and into the group III-Nitride channel layer toward a heterointerface; and
forming the drain to extend at least through the group III-Nitride barrier layer and into the group III-Nitride channel layer toward the heterointerface.

15. The process of implementing a high-electron mobility transistor (HEMT) of claim 13, further comprising:
forming the source to extend at least through the group III-Nitride barrier layer and into the group III-Nitride channel layer to a heterointerface; and
forming the drain to extend at least through the group III-Nitride barrier layer and into the group III-Nitride channel layer to the heterointerface.

16. The process of implementing a high-electron mobility transistor (HEMT) of claim 13, wherein the group III-Nitride barrier layer includes an upper surface and a lower surface; and wherein the process further comprises:
forming the source to extend vertically through the upper surface of the group III-Nitride barrier layer, through the lower surface of the group III-Nitride barrier layer, and through an upper surface of the group III-Nitride channel layer; and
forming the drain to extend vertically through the upper surface of the group III-Nitride barrier layer, through the lower surface of the group III-Nitride barrier layer, and through an upper surface of the group III-Nitride channel layer.

17. The process of implementing a high-electron mobility transistor (HEMT) of claim 16, further comprising:
forming the source to extend vertically through the upper surface of the group III-Nitride barrier layer, through the group III-Nitride barrier layer, through an upper surface of the group III-Nitride channel layer, and to a heterointerface; and
forming the drain to extend vertically through the upper surface of the group III-Nitride barrier layer, through the group III-Nitride barrier layer, through an upper surface of the group III-Nitride channel layer, and to the heterointerface.

18. The process of implementing a high-electron mobility transistor (HEMT) of claim 13, further comprising:
forming the gate to extend through the group III-Nitride barrier layer.

19. The process of implementing a high-electron mobility transistor (HEMT) of claim 13, further comprising:
forming the source to have a vertical depth of 90% to 110% of a thickness of the group III-Nitride barrier layer; and
forming the drain to have a vertical depth of 90% to 110% of a thickness of the group III-Nitride barrier layer.

20. The process of implementing a high-electron mobility transistor (HEMT) of claim 13, wherein:
the group III-Nitride barrier layer includes an upper surface and a lower surface;
the source is structured and arranged to have a lower surface;
the drain is structured and arranged to have a lower surface; and the process further comprising:
forming the lower surface of the source vertically below the lower surface of the group III-Nitride barrier layer; and
forming the lower surface of the drain vertically below the lower surface of the group III-Nitride barrier layer.

21. The process of implementing a high-electron mobility transistor (HEMT) of claim 20, wherein:
the lower surface of the source is on a heterointerface; and
the lower surface of the drain is on the heterointerface.

22. The process of implementing a high-electron mobility transistor (HEMT) of claim 20, wherein:
the lower surface of the source is within a heterointerface; and
the lower surface of the drain is within the heterointerface.

23. The process of implementing a high-electron mobility transistor (HEMT) of claim 13, further comprising forming a field plate.

24. The process of implementing a high-electron mobility transistor (HEMT) of claim 13, wherein a structural arrangement and configuration of the source and the drain reduces ON-state resistance RDS(on) by 4%-40%.
